(19) United States
(12) Patent Application Publication
(10) Pub. No.: US 2025/0359000 A1
(43) Pub. Date: Nov. 20, 2025

(54) Static Random-Access Memory Device with Enhanced Isolation Structure and Increased Packing Density

(71) Applicant: Taiwan Semiconductor Manufacturing Company, Ltd., Hsin-Chu (TW)

(72) Inventors: Jui-Lin Chen, Taipei City (TW); Feng-Ming Chang, Hsinchu County (TW); Ping-Wei Wang, Hsin-Chu (TW); Yu-Bey Wu, Hsinchu (TW)

(21) Appl. No.: 19/282,576

(22) Filed: Jul. 28, 2025

Related U.S. Application Data
(63) Continuation of application No. 18/411,620, filed on Jan. 12, 2024.
(60) Provisional application No. 63/517,415, filed on Aug. 3, 2023.

(51) Int. Cl. H10B 10/00

(52) U.S. Cl. CPC H10B 10/125; H10B 10/18

(57) ABSTRACT

The present disclosure provides an IC structure that includes a semiconductor substrate having a SRAM region, an input/output and peripheral (IOP) region, and an edge region spanning tween the SRAM region and the IOP region; a STI structure formed on the semiconductor substrate and defining active regions; a SRAM cell formed within the SRAM region; and a backside dielectric layer disposed on a backside of the semiconductor substrate and landing on a bottom surface of the STI structure. The active regions are longitudinally oriented along a first direction; gates are formed on the semiconductor substrate and are evenly distributed with a pitch P along the first direction; the SRAM cell spans a first dimension Ds along the first direction; the edge region spans a second dimension De along the first direction; and a ratio De/Ds equals to 2 or is less than 2.

### PRIORITY DATA

This application is a Continuation of U.S. patent application Ser. No. 18/411,620, filed Jan. 12, 2024, which further claims priority to U.S. Provisional Patent Application No. 63/517,415 filed on Aug. 3, 2023, entitled “SRAM INTEGRATED CIRCUIT LAYOUT WITH ENHANCED ISOLATION”, the entire disclosures of which are hereby incorporated herein by reference.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

Recently, multigate devices have been introduced to improve gate control. Multigate devices have been observed to increase gate-channel coupling, reduce OFF-state current, and/or reduce short-channel effects (SCEs). One such multigate device is the gate-all around (GAA) device, which includes a gate structure that can extend, partially or fully, around a channel region to provide access to the channel region on at least two sides. GAA devices enable aggressive scaling down of IC technologies, maintaining gate control and mitigating SCEs, while seamlessly integrating with conventional IC manufacturing processes. As GAA devices continue to scale, challenges have arisen in some areas, such as degraded device packing density and current leakage issues, especially for static random-access memory (SRAM) devices. Accordingly, although existing GAA SRAM devices and methods for fabricating such have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a top view of an integrated circuit structure having a static random-access memory (SRAM) structure according to various aspects of the present disclosure.

FIG. 2 is a schematic diagram of a SRAM structure according to various aspects of the present disclosure.

FIG. 3 is a top view of the SRAM structure according to various aspects of the present disclosure.

FIG. 4 is a top view of the integrated circuit structure, in portion, according to various aspects of the present disclosure.

FIG. 5 is a top view of the integrated circuit structure, in portion, according to various aspects of the present disclosure.

FIGS. 6A and 6B are top views of the integrated circuit structure, in portion, according to various embodiments of the present disclosure.

FIGS. 7A and 7B are sectional views of the integrated circuit structure, in portion, according to various aspects of the present disclosure.

FIG. 8A is a top view of an integrated circuit structure according to various aspects of the present disclosure.

FIGS. 8B, 8C and 8D are sectional views of the integrated circuit structure of FIG. 8A according to various aspects of the present disclosure.

FIG. 9A is a top view of an integrated circuit structure according to various aspects of the present disclosure.

FIG. 9B is a sectional view of the integrated circuit structure of FIG. 9A according to various aspects of the present disclosure.

FIGS. 10A, 10B and 10C are flowcharts of a method for fabricating the integrated circuit structure according to various aspects of the present disclosure.

FIGS. 11A, 12A, 13A, 14A, 15A and 16A are fragmentary perspective views of the integrated circuit structure, in portion or entirety, at various fabrication stages according to various aspects of the present disclosure.

FIGS. 11B, 12B, 13B, 14B, 15B and 16B are fragmentary sectional views of integrated circuit structure, in portion or entirety, at various fabrication stages according to various aspects of the present disclosure.

FIGS. 17, 18, 19, 20, 21, 22, 23 and 24 are fragmentary top views of integrated circuit structure, in portion or entirety, according to various aspects of the present disclosure.

### DETAILED DESCRIPTION

The present disclosure relates generally to integrated circuit devices, and more particularly, to multigate devices, such as gate-all-around (GAA) devices.

The following disclosure provides many different embodiments, or examples, for implementing different features. Reference numerals and/or letters may be repeated in the various examples described herein. This repetition is for the purpose of simplicity and clarity and does not in itself dictate a relationship between the various disclosed embodiments and/or configurations. Further, specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Moreover, the formation of a feature on, connected to, and/or coupled to another feature in the present disclosure may include embodiments in which the features are formed in direct contact, and may also include embodiments in which additional features may be formed interposing the features, such that the features may not be in direct contact.

Further, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used herein for ease of description to describe one element or feature's relationship to another element(s) or feature(s). The spatially relative terms are intended to encompass different orientations than as depicted of a device (or system or apparatus) including the element(s) or feature(s), including orientations associated with the device's use or operation. The apparatus may be otherwise oriented (rotated 90 degrees or at other orientations) and the spatially relative descriptors used herein may likewise be interpreted accordingly.

Still further, when a number or a range of numbers is described with “about,” “approximate,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm.

The disclosed device structure and the method making the same are related to field-effect transistors (FETs), especially FETs having multiple channels vertically stacked, such as gate-all-around (GAA) FET structure. The disclosed device structure includes various structure features and fabrication steps to provide collective isolation and prevent the device structure from current leakage. The disclosed structure is related to an integrated circuit structure having static random-access memory (SRAM) cells configured into an array. Particularly, the present disclosure provides a SRAM circuit having GAA structure with enhanced isolation and corresponding SRAM circuit layout with reduced size.

In the current SRAM structure, the current leakage is a concern, especially when high circuit speed is desired. A SRAM cell includes two cross-coupled inverters for data storage and two pass gates for input/output. In some embodiments, the SRAM cell includes six or more FETs, such as 6 FETs or 8 FETs. In furtherance of the embodiments, the SRAM cell includes N-type FETs (nFETs) and N-type FETs (nFETs). In some situation, the current leakage is overcome by doped wells and well pickups to bias the doped well to achieve junction isolation. For example, the SRAM circuit structure includes a P-well and a deep N-well (DNW) underlying the P-well, and a P-well pickup for biasing the P-well and a N-well pickup for biasing the deep N-well. This structure may reduce the current leakage but increase device area for additional well pickup regions and reduce the circuit packing density.

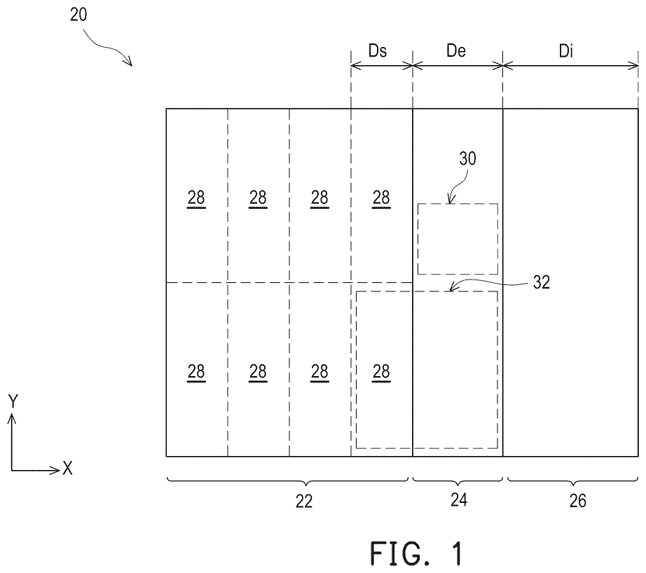

FIG. 1 is a top view of an integrated circuit (IC) structure 20 having various circuit regions including a SRAM region 22, an input/output and peripheral (IOP) region 26, and an edge region (or edge cell) 24 spanning between the SRAM region 22 and the IOP region 26. The SRAM region, the edge region 24 and the IOP region 26 are configured along X direction and extends along Y direction with a same dimension. The SRAM region 22 includes a plurality of SRAM cells 28 configured in an array. The IOP region 26 includes various input, output and peripheral devices formed therein. The IOP devices are designed differently for input/output (I/O) and peripheral devices. For example, an I/O field-effect transistor includes a gate dielectric layer thicker than other FETs in a SRAM cell due to high power surge, electrostatic discharge (ESD), and other I/O environment challenges. The edge region 24 is a region interposed between the SRAM region 22 and the IOP region 26 to provide a transition and buffer region between the SRAM region 22 and the IOP region 26. In the previous structure, the edge region occupies greater circuit area due to the pickup areas for junction isolation for the substrate. The disclosed structure includes various dielectric isolation features to provide collective isolation function and the edge region 24 is substantially reduced.

In some embodiments of the present disclosure, the method to form a device structure includes, after forming FETs in fin structure or GAA structure, includes operations to thin down the substrate from the backside to reach the bottom surface of the shallow trench isolation (STI) structure so that the semiconductor substrate is separated into a plurality of semiconductor islands that are isolated from each other by the STI structure, thereby achieving isolation of those semiconductor islands and reduction of leaking current. Thus, those well pickup regions for junction isolation are eliminated with the circuit area reduction more than 80%. Therefore, the disclosed device structure is also referred to as tap-less device structure. The edge region 24 spans a dimension De along X direction while a SRAM cell 28 spans a dimension Ds along X direction. In some embodiments, a ratio De/Ds equals to 2 or is less than 2.

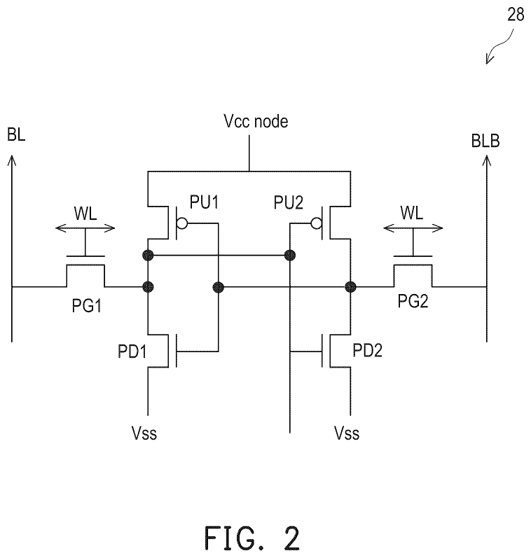

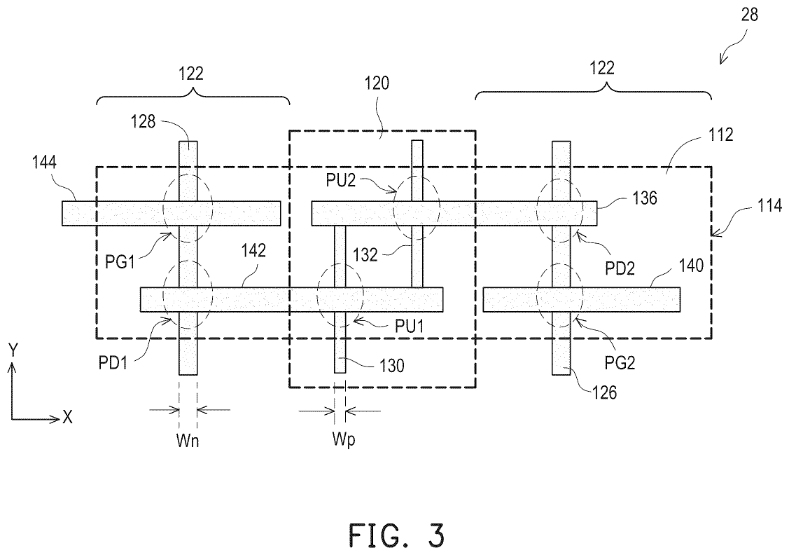

A SRAM cell is further illustrated in FIGS. 2 and 3 according to some embodiments. FIG. 2 is a schematic view of the SRAM cell 28 constructed according to various aspects of the present disclosure in one embodiment. FIG. 3 is a top view of the SRAM cell constructed according to various aspects of the present disclosure in one embodiment.

Referring to FIG. 2, the SRAM cell 28 is formed on fin active regions and includes various FETs, such as fin FETs (FinFETs), GAA FETs or other suitable FETs. The SRAM cell 28 includes a first inverter and second inverter that are cross coupled to form a data storage unit. The first inverter includes a first pull-up device (PU1) formed with a p-type field-effect transistor (pFET). The first inverter also includes a first pull-down device (PD1) formed with one or more n-type field-effect transistor (nFET). The second inverter includes a second pull-up device (PU2) formed with a pFET. The second inverter also includes a second pull-down device (PD2) formed with one or more nFETs. The SRAM cell 28 further includes various pass gate devices (PG1 and PD2) connected to the cross-coupled inverters and configured to form two ports for reading and writing.

The SRAM cell 28 is further described with detailed layout in FIG. 3 in accordance with some embodiments. The SRAM cell 28 includes is formed on a semiconductor substrate. The semiconductor substrate includes silicon. Alternatively, the substrate includes germanium, silicon germanium or other proper semiconductor materials. The semiconductor substrate may include other proper features and structures. In one embodiment, the semiconductor substrate employs a layer of semiconductor material formed over an insulating layer on a supporting bulk wafer for isolation. The technology and structure are referred to as semiconductor on isolation (SOI). The SOI structure can be formed by different techniques including separation by implanted oxygen (SIMOX), bonding and etching back (BESOI), and zone melting and recrystallization (ZMR).

The SRAM cell 28 is formed in a unit cell region 112 of the semiconductor substrate. The unit cell region 112 is defined by the unit cell boundary 114. In one embodiment, the unit cell region 112 is defined in a rectangular shape spanning to a first dimension Ds along X direction and spanning to a second dimension Ds2 along Y direction perpendicular to X direction. Ds2 is longer than Ds. T In one embodiment, a ratio of the second dimension over the first dimension is greater than 3. The SRAM cell 28 includes an N-well 120 disposed in the middle portion of the cell; and a P-well 122 disposed on the both sides of the N-well 120. In one embodiment, the N-well 120 and P-well 122 are extended to multiple cells beyond the unit cell boundary. For example, the N-well 120 and P-well 122 are extended to 4 or more cells in the second direction.

Various active regions are defined in the substrate by isolation features and are isolated from each other by the isolation features. The isolation features are formed in the semiconductor substrate with a proper technology. In one embodiment, the isolation features are formed by shallow trench isolation (STI) technique. In another embodiment, the formation of the STI features includes etching a trench in a substrate and filling the trench by one or more insulator materials such as silicon oxide, silicon nitride, or silicon oxynitride. The filled trench may have a multi-layer structure such as a thermal oxide liner layer with silicon nitride filling the trench. The active regions are defined in the semiconductor substrate upon the formation of the isolation features.

The SRAM cell 28 utilizes plain active regions to form plain FETs, fin active regions to form FinFETs; GAA structure to form GAA FETs or other structure to form corresponding FETs. For example, fin active regions are formed by a suitable technology and may be formed in a process to form both the STI features and the fin active regions. In one embodiment, the fin active regions are formed by a process including etching the semiconductor substrate to form trenches, partially filling the trenches to form shallow trench isolation (STI) structure surrounding each fin active region. In furtherance of the present embodiment, an epitaxy semiconductor layer is selectively formed on the fin active region. In another embodiment, the fin active regions are formed by a process including depositing a dielectric material layer on a semiconductor substrate, etching the dielectric material layer to form openings thereof, and selective epitaxy growing a semiconductor material (such as silicon) on the semiconductor substrate within the openings to form fin active regions and the isolation features. In yet another embodiment, the various FETs may include strained features for enhanced mobility and device performance. For example, pFETs include epitaxy grown silicon germanium on a silicon substrate. n-type nFETs include epitaxy grown silicon carbide on the silicon substrate. In GAA FETs, the semiconductor substrate further includes a semiconductor stack with two different semiconductor materials alternatively stacked. In some embodiments, the semiconductor stack includes a first semiconductor layers of silicon and a second semiconductor layers of silicon germanium alternatively stacked. During the formation of the fin active fins and the STI structure, the semiconductor stack is patterned as well.

In one embodiment, the SRAM cell 28 includes a first active region 126 and second active region 128 formed in the P-well 122. The SRAM cell 100 further includes a third active region 130 and a fourth active region 132 formed in the N-well 120. All active regions 126 through 132 are disposed in parallel and oriented along X direction. The first through fourth active regions or a subset thereof may be extended to multiple cells, such as 4 or more cells in the second direction.

In some embodiments, each of the active regions includes one or more fin active features configured to form various FinFETs. In yet some embodiments, each of the active regions includes multiple channel layers vertically stacked to form one or more GAA FETs. Each of the active regions 126 and 128 in the P-well 122 includes active regions with a first dimension Wn along Y direction; and each of the active regions 130 through 132 in the N-well 120 includes a second width Wp along Y direction. In some embodiments, Wp is different from Wn. In furtherance of the embodiments, Wn is greater than Wp, or a ratio Wn/Wp is greater than 1, such as being greater than 2 or 3. This layout is also referred to as high current layout since nFETs are designed with high current to increase reading and writing of the SRAM cell. In the active regions 126 and 128, nFETs are formed, such as two pull-down devices (PDs), two pass-gate devices (PGs). In the active regions 130 and 132, pFETs are formed, such as two pull-up devices (PUs).

Gate structures are formed over various active regions and engage portions of the corresponding active regions as channels with configuration to form nFETs and pFETs. The gate structures include a gate dielectric layer and a gate electrode disposed over the gate dielectric layer and gate spacers disposed on sidewalls of the gate electrode. The gate dielectric layer includes silicon oxide, high-k dielectric material including metal oxide or metal nitride (such as hafnium oxide and hafnium nitride), other suitable dielectric material or a combination thereof. The gate electrode includes metal (such as aluminum, copper, and tungsten), alloy, other proper conductive materials or a combination thereof. In some embodiments, the gate electrode further includes metal (or metal alloy) layer having proper work function to tune the threshold voltage of the corresponding FET. Those metal layers for nFETs and pFETs are referred to as a n-type work function metal layer and a p-type work function metal layer, respectively. The n-type and p-type work function metal layers are different for nFETs and pFETs in composition. In some embodiments, the n-type work function metal layer includes tantalum (Ta), titanium aluminum (TiAl), titanium aluminum carbide (TiAlC), titanium aluminum oxide (TiAlO), titanium aluminum nitride (TiAlN) or a combination thereof. In some embodiments, the p-type work function metal layer includes titanium nitride (TiN), tantalum nitride (TaN), tungsten nitride (WN) or a combination thereof. The gate dielectric layer and the gate electrode are collectively referred to as gate stack. The gate structures are disposed in parallel and longitudinally oriented along Y direction. The SRAM cell 28 includes gate structures 136, 140, 142 and 144.

Gate structures 136, 140, 142 and 144 and configured with the active regions 126, 128, 130 and 132 to form nFETs and pFETs for PD devices, PU devices and PG devices integrated into a SRAM cell as illustrated in FIG. 3, according to some embodiments. Particularly, the gate structure 136 extends from the P-well 122 to the N-well 120; the gate structure 142 extends from the P-well 122 to the N-well 120; the gate structure 140 is disposed in the P-well 122 and the gate structure 144 is disposed in the P-well 122. The active region 128 and the gate structure 144 forms PG1; the active region 128 and the gate structure 142 forms PD1; the active region 130 and the gate structure 142 forms PU1; the active region 130 and the gate structure 136 forms PU2; the active region 126 and the gate structure 136 forms PD2; and the active region 126 and the gate structure 140 forms PG2. The SRAM cell 28 further includes other features, such as source/drain features and an interconnect structure having contacts, vias and metal lines distributed in multiple metal layers, which are not illustrated in FIG. 3 for simplicity and but will be described with other figures.

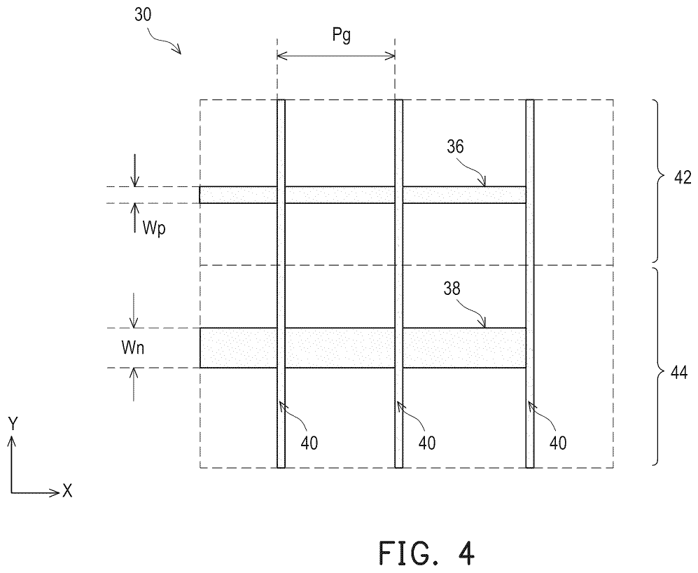

The edge region 24 is further described with reference to FIG. 4. FIG. 4 is a top view of the edge region 24 in portion (particularly a portion 30 indicated by a dashed line box in FIG. 1), constructed according to some embodiments. The structure and dimensions of the edge region 24 are designed to provide effective and efficient isolation between the SRAM region 22 and the IOP region 26 with eliminated or reduced interference therebetween while the edge region 24 occupies minimum circuit area.

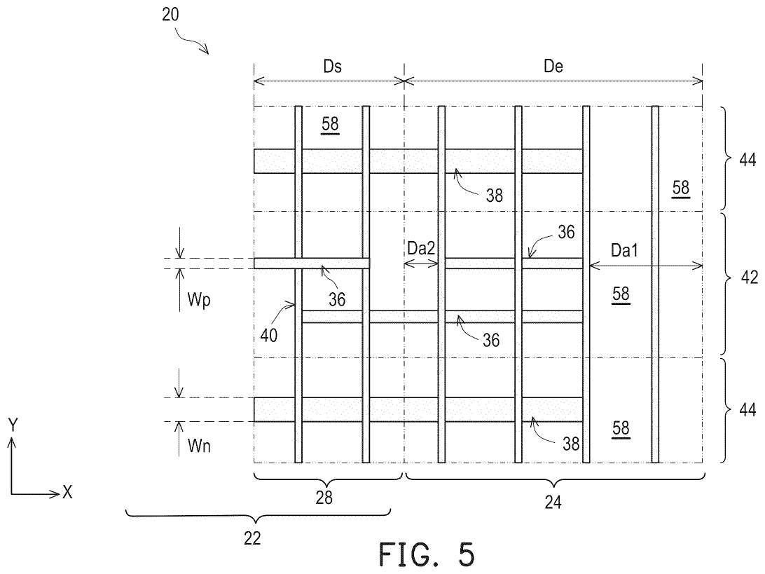

The edge region 24 includes a N-well 42 and a P-well 44 sharing a common longitudinal side. The N-well 42 and the P-well 44 are longitudinally oriented along X direction. In some embodiments, the N-well 42 and the P-well 44 are continuously extending from the SRAM region 22 to the edge region 24, which will be further described later, such as in FIG. 5.

The edge region 24 also includes a first active region 36 formed in the N-well 42 and a second active region 38 formed in the P-well 44. The first active region 36 and the second active region 38 are longitudinally oriented along X direction. In some embodiments, at least one of the first active region 36 and the second active region 38 is continuously extending from the SRAM region 22 to the edge region 24.

The active region 36 in the N-well 42 spans a first width Wp along Y direction; and the active region 38 in the P-well 44 spans a second width Wn along Y direction. In some embodiments, Wp is different from Wn. In furtherance of the embodiments, Wn is greater than Wp, or a ratio Wn/Wp is greater than 1, such as being greater than 2 or 3.

The edge region 24 also includes gate structures 40 disposed in parallel and longitudinally oriented along Y direction. In the disclosed embodiment, the edge region 24 includes gate structures 40 disposed over the active regions or over an edge of the active regions, as illustrated in FIG. 4. The gate structures 40 are similar to the gate structures in FIG. 3 in terms of formation and composition. Similar descriptions are not repeated for simplicity. The gate structures 40 are evenly distributed along X direction with a periodic dimension Pg or CPP. Pg is defined as a distance from one gate structure to an adjacent gate structure, measured from center to center or side to same side. In some embodiments, Pg ranges between 40 nm and 50 nm.

A portion 32 of the IC structure 20 in FIG. 1 is further illustrated in FIG. 5. FIG. 5 is a top view of the IC structure 20, in portion, constructed according to various aspects of the present disclosure. Particularly, the portion 32 of the IC structure 20 includes both a SRAM cell 28 and the edge region 24, which are collectively described with reference to FIG. 5.

The IC structure 20 includes a N-well 42 and a P-well 44 longitudinally oriented along X direction. The P-well 44 includes two portions with the N-well 42 inserted and spanning between the two portions of the P-well 44 along Y direction. In the disclosed embodiment, the N-well 42 and the P-well 44 are continuously extending from the edge region 24 to the SRAM region 22 along X direction or beyond the SRAM cell 28, such as extending through the SRAM region 22 of multiple SRAM cells in array.

The IC structure 20 also includes first active regions 36 disposed in the N-well 42 to form various pFETs for PU devices of the SRAM cell 28 and second active regions 38 disposed in the P-well 44 to form various nFETs for PD devices and PG devices of the SRAM cell 28. The first active regions 36 and the second active regions 38 are longitudinally oriented along X direction. In the disclosed embodiments, the second active regions 38 are continuously extending from the edge region 24 to the SRAM region 22 and further extending through the SRAM cell 28 along X direction. At least one of the first active regions 36 is continuously extending from the edge region 24 to the SRAM region 22. Specifically, one of the first active region 36 disposed in the SRAM cell 28 and another first active region 36 disposed in the edge region 24 are distance from each and aligned along X direction. Yet another first active region 36 is continuously extending from the edge region 24 to the SRAM cell 28.

Furthermore, the first active regions 36 in the N-well 42 spans a first width Wp along Y direction; and the second active region 38 in the P-well 44 spans a second width Wn along Y direction. In the disclosed embodiments, Wp is different from Wn. In furtherance of the embodiments, Wn is greater than Wp, or a ratio Wn/Wp is greater than 1, such as being greater than 2 or 3, thereby increasing the currents to the PG devices and PD devices, increasing the speed and enhancing the performance of the SRAM cell 28.

The IC structure 20 further includes gate structures 40 configured in parallel and longitudinally oriented along Y direction. The gate structures 40 are disposed over the active regions and are extended to the STI structure 58. Note that the active regions are surrounded by the STI structure so that the STI structure is defined in any other areas not being occupied by the active regions in the top view of the IC structure 20.

The gate structures 40 are evenly distributed along X direction with a periodic dimension Pg. Pg is defined as a dimension from one gate structure to an adjacent gate structure, measured from same location such as center to center or side to same side. As described above, the edge region 24 spans a dimension De and the SRAM cell 28 spans a dimension Ds along X direction. In the present embodiment, De=4Pg and Ds=2Pg, or a ratio De/Ds=2. In some other embodiments described below, a ratio De/Ds is less than 2, such as 1.5 or 1. In some embodiments, Pg ranges between 40 nm and 50 nm; and De ranges between 160 nm and 200 nm in the case De=4Pg. In some embodiments, Pg ranges between 40 nm and 50 nm; and De ranges between 80 nm and 100 nm in the case De=2Pg. The spacing Da1 between the end of the active regions and the boundary line of the edge region 24 equals to 1.5*Pg according to some embodiment. The spacing Da2 between the end of the active regions and the boundary line of the SRAM region 22 equals to 0.5*Pg according to some embodiment. Minimum length of the active regions equals to 2*Pg according to some embodiments.

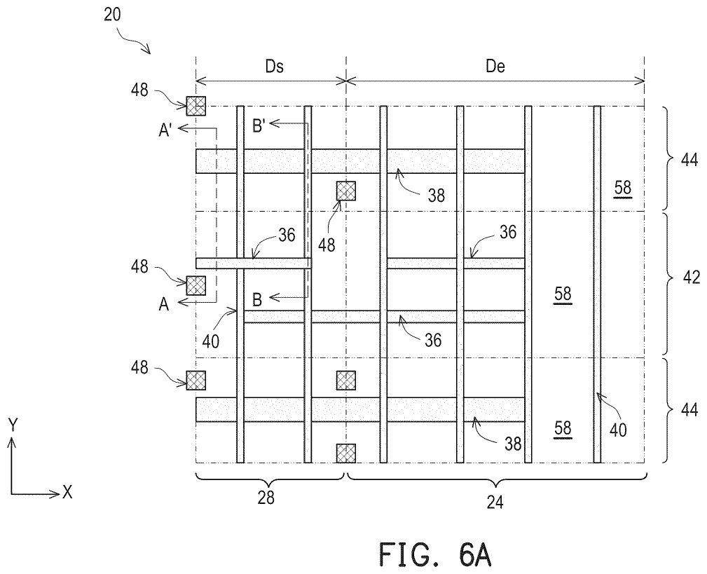

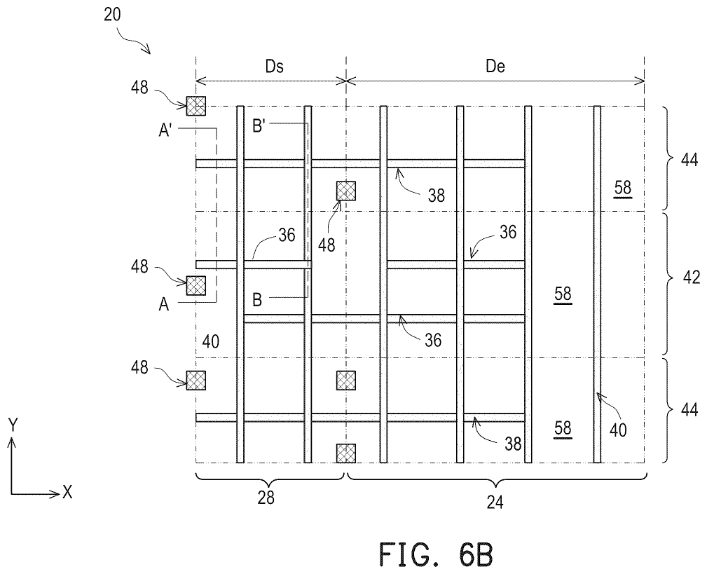

The IC structure 20 is further described with reference to FIGS. 6A and 6B. FIGS. 6A and 6B are top views of the IC structure 20, in portion, constructed according to various embodiments of the present disclosure. Like FIG. 5, only the portion 32 of the IC structure 20 is illustrated, which includes both a SRAM cell 28 and the edge region 24. FIG. 6A is similar to FIG. 5 but further includes via features (or simply vias) 48 formed on the substrate. The via features 48 is electrically connected to various features, such source/drain (S/D) features of the FETs. For example, the via features 48 are formed on the frontside of the substrate and are electrically connected to the S/D features through contact features. In some embodiments, the via features 48 are formed from the backside of the substrate and electrically connected to the bottom surfaces of the corresponding S/D features. The via features 48 formed on the backside of the substrate are also referred to as backside vias (VB).

FIG. 6B is similar to FIG. 6A but the widths of the active regions 36 and 38 are the same or the ratio Wn/Wp=1.

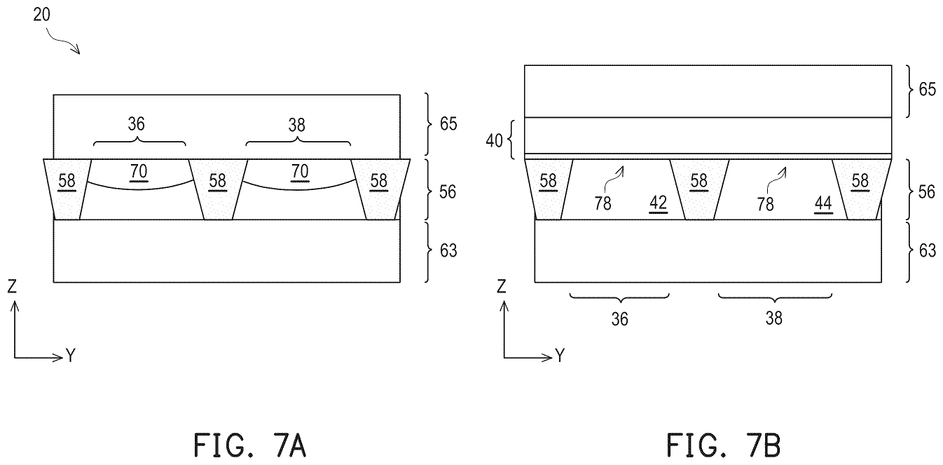

The IC structure 20 is further described with reference to FIGS. 7A and 7B. FIGS. 7A, and 7B are sectional views of the IC structure 20, in portion, cut along the dashed lines AA′ and BB′ of FIG. 6A or 6B, respectively, constructed according to various embodiments of the present disclosure.

Referring to FIGS. 7A through 7B, the IC structure 20 includes a semiconductor substrate 56, such as a silicon substrate, a gallium arsenide substrate, or other suitable semiconductor substrate. An isolation structure 58 is formed in the semiconductor substrate 56 and separates various portions of the semiconductor substrate 56 along Y direction, defining active regions 36 and 38 of the semiconductor substrate 56. Those active regions 36 and 38 are surrounded by the isolation structure 58 and separated from each other by the isolation structure 58. In the present disclosure, the isolation structure 58 are shallow trench isolation (STI) structure formed by a proper procedure that includes patterning, deposition, and chemical mechanical polishing (CMP). Those active regions 36 and 38 may be extruded above the STI structure 58 and are referred to as fin active regions accordingly. The IC structure 20 includes various field-effect transistors (FETs) formed on the active regions. A field-effect transistor includes a gate structure 40, source/drain (S/D) features 70 interposed by the gate structure 40, and channel regions 78 underlying the gate structures 40. The gate structure 40 includes a gate dielectric layer and a gate electrode disposed on the gate dielectric layer, and a gate spacer disposed on sidewalls of the gate electrode. In various embodiments, the FETs may be planar FETs, fin FETs, multi-gate FETs such as a gate-all-around (GAA) FET or other suitable FET structures. The FETs are formed on the frontside of the semiconductor substrate 56. The method to form the IC structure includes thinning down the semiconductor substrate 56 from the backside such that the STI structure 58 are exposed. The bottom surface of the semiconductor substrate 56 and the bottom surface of the STI structure 58 are coplanar after thin-down. Other structures, such as an interconnect structure 65, are formed on the frontside of the semiconductor substrate 56. Backside interconnect structure 63 is formed on the backside of the semiconductor substrate 56 after thin-down.

The above disclosed structure provides isolation for various FETs distributed along Y direction (along longitudinal direction of gates). However, various FETs distributed along X direction (along longitudinal direction of active regions such as fin active regions) on one active region are not properly isolated from each other by the STI structure 58. The IC structure 20 in the present disclosure further includes multiple features to collectively achieve enhanced isolation for those FETs, especially along X direction) as described below.

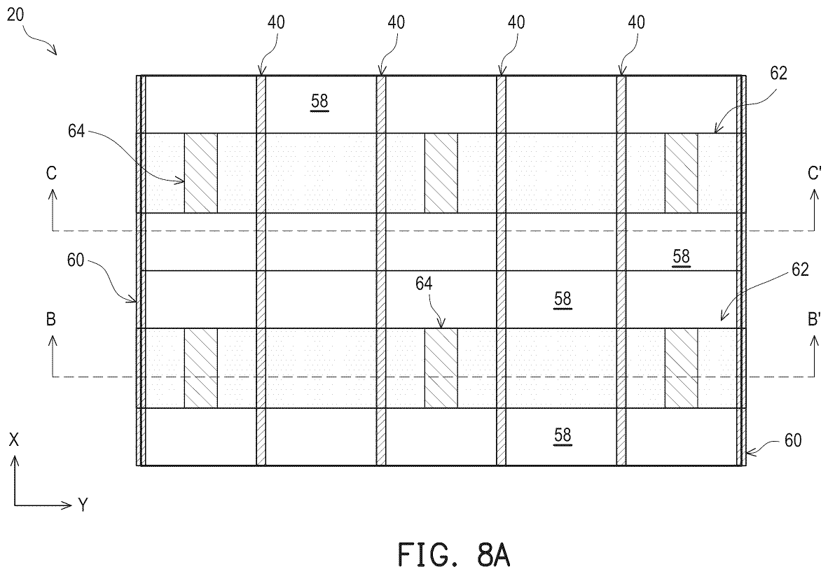

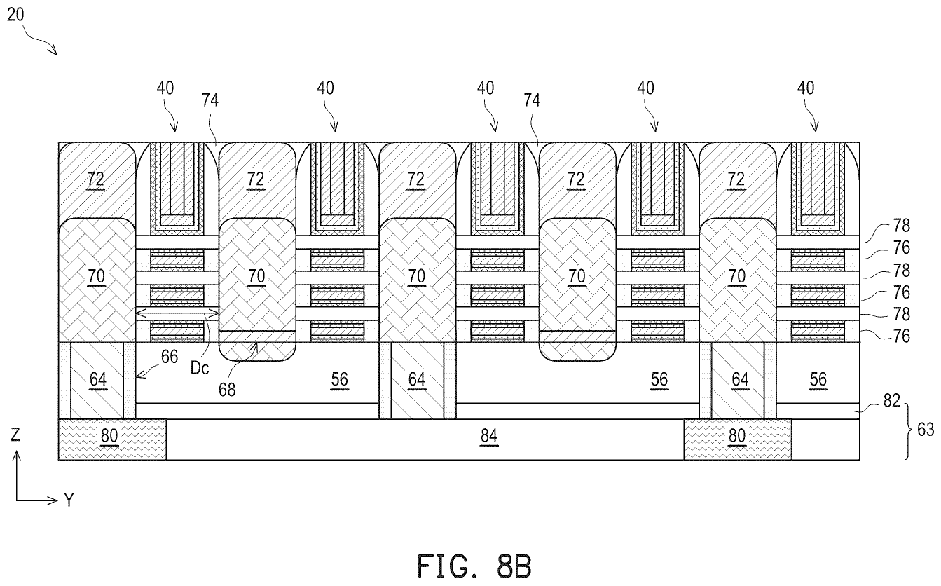

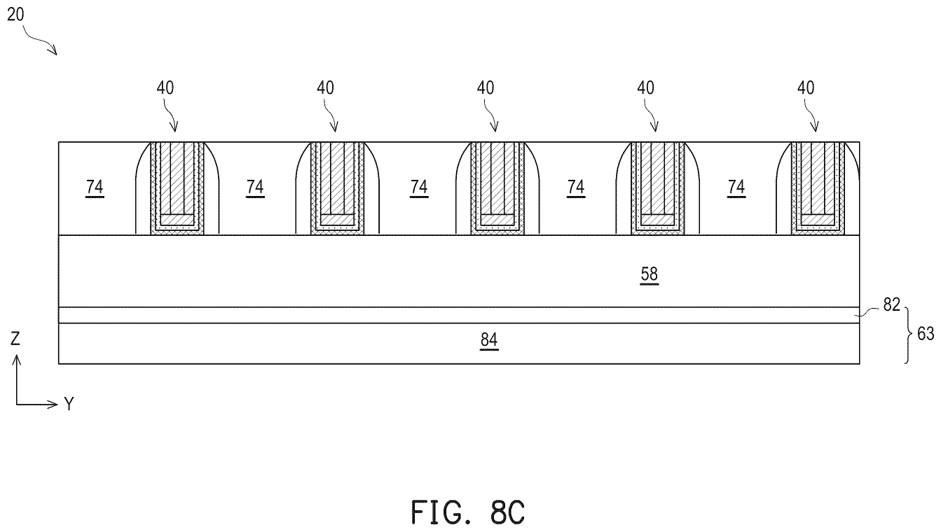

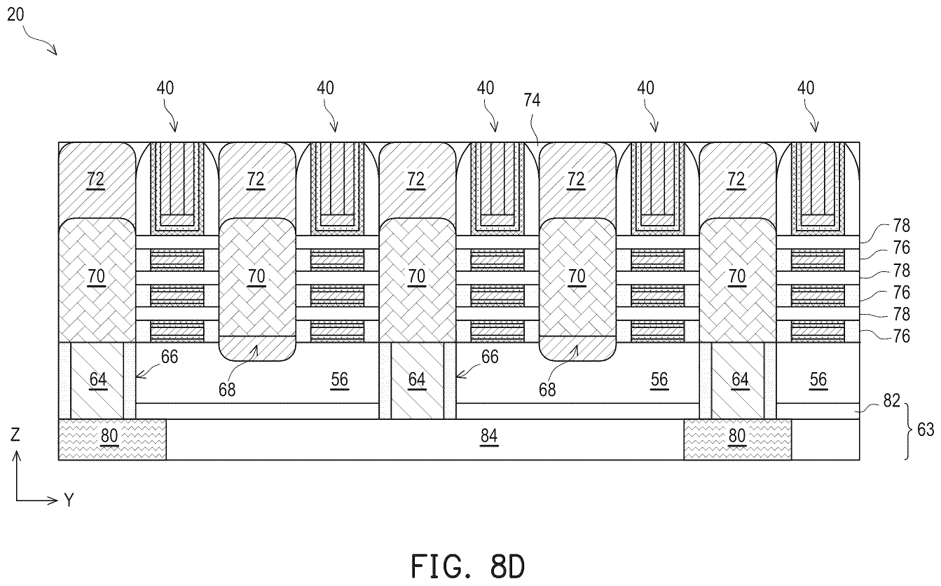

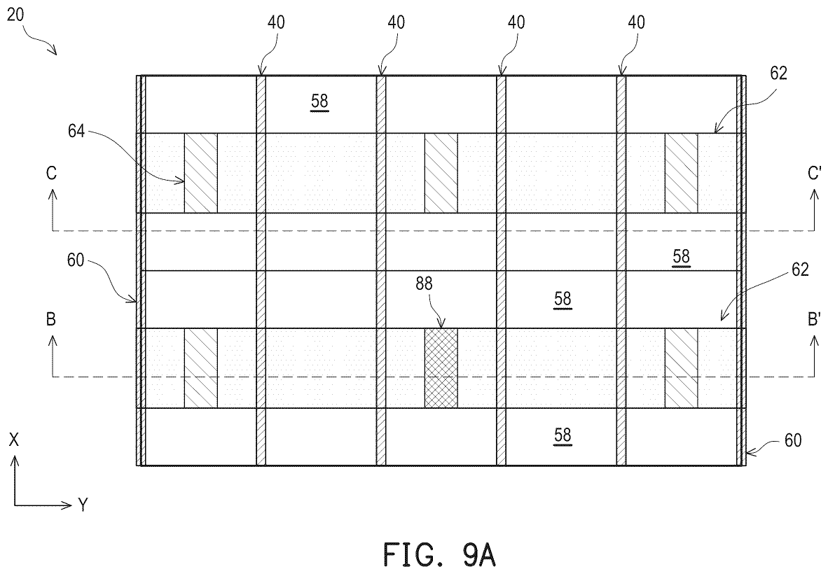

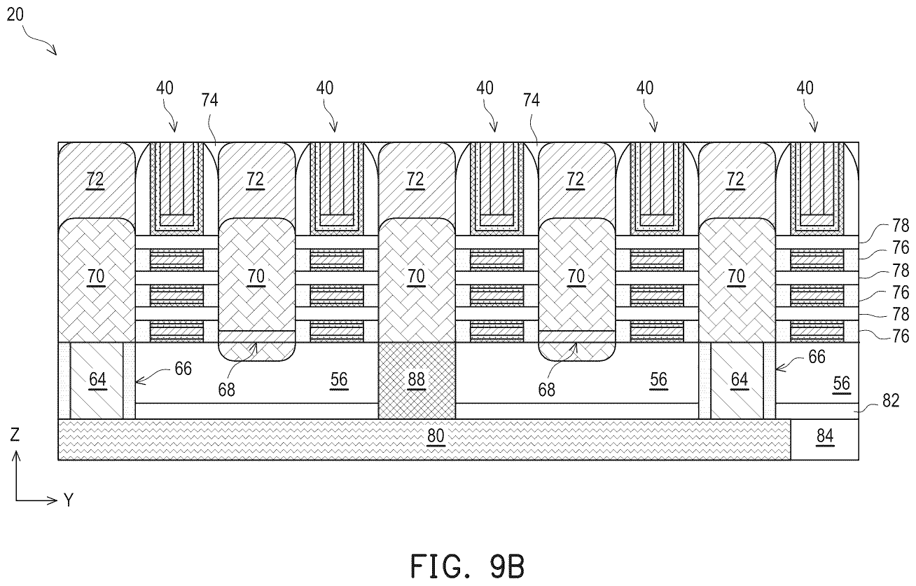

FIG. 8A illustrates a top view of the IC structure 20 while FIGS. 8B (and 8D) and 8C illustrate sectional views of the IC structure 20 along the dashed lines BB′ and CC′, respectively, constructed according to some embodiments. In FIG. 8A, the device structure includes active regions 62 oriented along X direction and gate structures 40 oriented along Y direction. The active regions 62 may include some (such as 36) formed the N-well and some (such as 38) formed in the P-well. Backside vias (or “VB”) 64 are formed from the backside of the substrate 56. The backside vias 64 are conductive features and are portions of the backside interconnect structure 63 for electrical routing. The backside vias 64 are electrically connected to FETs, such as connected to S/D features 70 from the backside. In some embodiments, a subset of the backside vias 64 are replaced by backside dielectric vias for isolation function, such as those illustrated in FIGS. 9A and 9B. The backside dielectric vias are dielectric features and are different from the backside conductive vias. The formation of the backside conductive vias and the backside dielectric features will be further described later.

In FIG. 8B, Various devices including FETs such as GAA FETs are formed on the frontside of the substrate 56. The FETs includes vertically stacked multiple channel layers 78, source/drain (S/D) features 70, and gate structures 40 interposed between the S/D features 70 and overlying the channel layers 78. The gate structures 40 further extend to wrap around each of the vertically stacked channel layers 78. The gate structures 40 includes a gate dielectric layer, a gate electrode disposed on the gate dielectric layer, and a gate spacer disposed on sidewalls of the gate electrode.

Furthermore, the S/D features 70 are formed with a dielectric feature (or dielectric layer) 68 embedded, thereby achieving the corresponding S/D features 70 from the semiconductor substrate 56. The dielectric feature 68 may include any suitable dielectric material, such as silicon nitride, silicon oxide, silicon oxynitride, other suitable dielectric material or a combination thereof. The formation of the S/D features 70 with the dielectric layer embedded therein may include etching to recess the S/D regions; epitaxially growing a semiconductor material with a lower doping concentration (such as doped with phosphorous for N-type FETs or with boron for P-type FETs); forming dielectric features 68; and epitaxially growing the semiconductor material with a higher doping concentration. The semiconductor material may include silicon, silicon germanium, or other suitable semiconductor material. The forming of the dielectric feature 68 may include depositing the dielectric material(s) and an anisotropic etching such as plasma etch to remove the portions deposited on sidewalls of the recesses.

In some alternative embodiments, the dielectric feature 68 is formed on the bottom surface of the epitaxial S/D feature 70 as illustrated in FIG. 8D. FIG. 8D is a sectional view of the IC structure 20 constructed according to some embodiments. FIG. 8D is similar to FIG. 8B but the dielectric feature 68 is formed on the bottom surface of the S/D feature 70. For example, the formation of the S/D features 70 with the dielectric layer embedded therein may include etching to recess the S/D regions; forming dielectric features 68; and epitaxially growing a semiconductor material with a lower doping concentration (such as doped with phosphorous for N-type FETs or with boron for P-type FETs). The epitaxially growing process may include epitaxially growing a semiconductor material with a lower doping concentration and epitaxially growing the semiconductor material with a higher doping concentration. The forming of the dielectric feature 68 may include depositing the dielectric material(s) and an anisotropic etching such as plasma etch to remove the portions deposited on sidewalls of the recesses.

A frontside interconnect structure is further formed over the FETs. The frontside interconnect structure includes contacts, vias and metal lines distributed in multiple metal layers. Some features (such as contacts 72) of the frontside interconnect structure are illustrated in FIG. 8B. For example, an interlayer dielectric (ILD) layer 74 is formed over the FETs by a proper procedure such as a procedure including deposition and CMP. The ILD layer 74 may include an etch stop layer and a low-k dielectric material disposed on the etch stop layer. The ILD layer 74 is patterned to form contact holes; one or more metal or other conductive material is deposited in the contact holes; and a CMP process is applied to remove excessive metal and planarize the top surface, thereby forming contacts 72 aligned with, landing on and electrically connected to corresponding S/D features 70.

The IC structure 20 also includes the backside vias 64 and other conductive features of the backside interconnect structure 63, such as metal lines 80. In some embodiments, after the formation of the FETs (and other devices) and frontside an interconnect structure over FETs, a carrier substrate may be bonded to the frontside. Thereafter, the semiconductor substrate 56 is thinning down from the backside such that the STI structure 58 is exposed from the backside. Other processes may be additionally applied to planarize the backside surface, such etching, deposition, and chemical mechanical polishing (CMP). Accordingly, the bottom surface of the substrate 56 and the bottom surfaces of the STI structures 58 are coplanar. The backside dielectric layer 82 is deposited on the backside and directly contacts the coplanar bottom surfaces of the semiconductor substrate 56 and the STI structures 58, as illustrated in FIGS. 8B and 8C. The backside dielectric layer 82 includes one or more suitable dielectric material such as silicon nitride, silicon oxide, or a combination thereof.

The backside vias 64 are formed in the semiconductor substrate 56 and are electrically connected to the S/D features 70 as illustrated in FIG. 8B. Each of the backside vias 64 includes a metal plug (also referred by a numeral 64) and a dielectric barrier layer 66 surrounding the sidewalls of the backside vias to provide isolation between the adjacent semiconductor islands and the metal plug. In some embodiments, the dielectric barrier layer 66 includes silicon nitride, other suitable dielectric material or a combination thereof. The metal plug 64 includes one or more metal such as copper, tungsten, other suitable metal or a combination thereof. The formation of the backside vias 64 includes patterning the backside dielectric layer 82 and the semiconductor substrate 56 to form open holes with corresponding S/D features 70 exposed therewithin; depositing a dielectric barrier material; performing a plasma etching process to remove the portions of the dielectric barrier material deposited on sidewalls of the open holes; depositing the metal to fill in the open holes; and performing a CMP process to planarize, according to some embodiments. Especially, the backside dielectric layer 82 and the dielectric barrier layer 66 surround the semiconductor islands of the semiconductor substrate 56, therefore providing enhanced isolation and reducing the leakage issues.

A backside interlayer dielectric (ILD) layer 84 is formed on the backside dielectric layer 82. The backside ILD layer 84 includes one or more dielectric material, such as an etch stop layer and a low-k dielectric material by suitable technique, such as chemical vapor deposition (CVD), spin-on coating, other suitable technique, or a combination thereof.

Other conductive features, such as metal lines (or backside metal lines) 80, are formed in the backside ILD layer 84 and electrically connected to the backside vias 64 as illustrated in FIG. 8B. The formation of the metal lines 80 may include any proper procedure such as a dual damascene process. For example, the backside ILD layer 84 is patterned to form trenches by lithography process and etching; one or more metal, such as a barrier layer (e.g., titanium and titanium nitride) and a filling metal are sequentially deposited in the trenches; and performing a CMP process to remove excessive deposited metal and planarize the surface.

In FIG. 8B, a first subset of the S/D features 70 are associated with backside vias 64 while a second subset of the S/D features 70 are free of the backside vias 64. The second subset of the S/D features 70 include dielectric feature 68 embedded therein for isolation while the first subset of the S/D features 70 are free of the dielectric feature 68 since those S/D features 70 are intended to be electrically connected to the backside vias 64. The channel length Dc is less than Pg. In some embodiments, the ratio Pg/Dc ranges between 2 and 4.

As noted above, the backside vias 64 may have some alternative structure described in FIGS. 9A and 9B. FIG. 9A illustrates a top view of the IC structure 20 while FIG. 9B illustrates a sectional view of the IC structure 20 along the dashed line BB′, constructed according to some embodiments. The IC structure 20 illustrated in FIGS. 9A and 9B is similar to the IC structure 20 illustrated in FIGS. 8A-8B. However, some backside vias 64 are replaced with backside dielectric vias 88. The backside dielectric vias 88 are dielectric features and are configured for isolation with enhance isolation effectiveness. Therefore, the semiconductor islands of the semiconductor substrate 56 are separated and isolated from each other by the backside dielectric vias 88. For clarity, the backside vias 64 are also referred to as backside conductive vias 64.

In FIG. 9A, the device structure includes active regions oriented along X direction and gates oriented along Y direction. Furthermore, the backside dielectric layer 82, the dielectric feature 68, the dielectric barrier layer 66, and the backside dielectric vias 88 are configured to collectively isolate one semiconductor island from adjacent semiconductor islands. In some embodiments, the device structure includes dielectric gate, dielectric gate-cut feature or both to provide additional isolation effect to the semiconductor islands and the FETs formed thereon.

Additional features and methods may be used for further isolation. For example, as illustrated in FIG. 9B, the metal line 80 on the backside is extended along X direction. In FIG. 8B, the metal line 80 on the backside is segmented with a dielectric feature (such as the backside ILD layer 84) inserted to provide additional isolation.

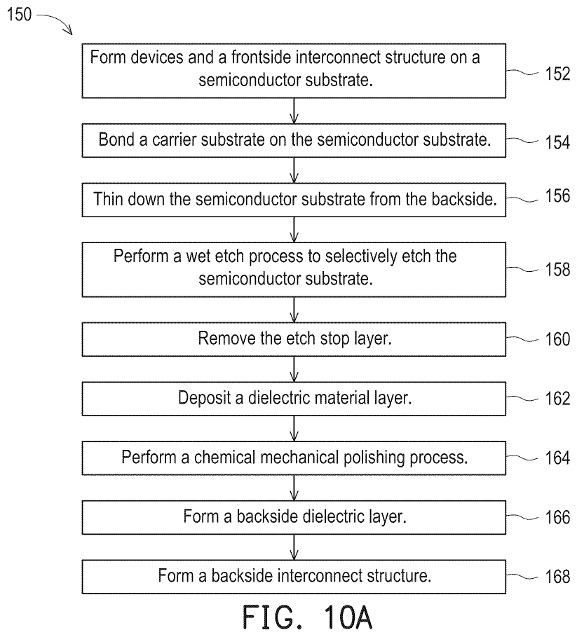

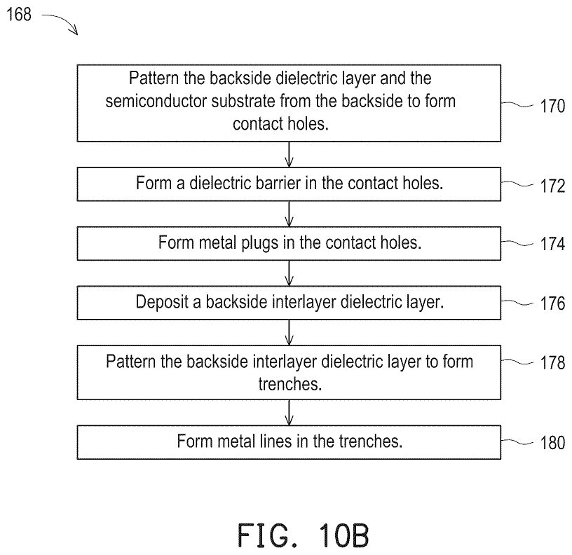

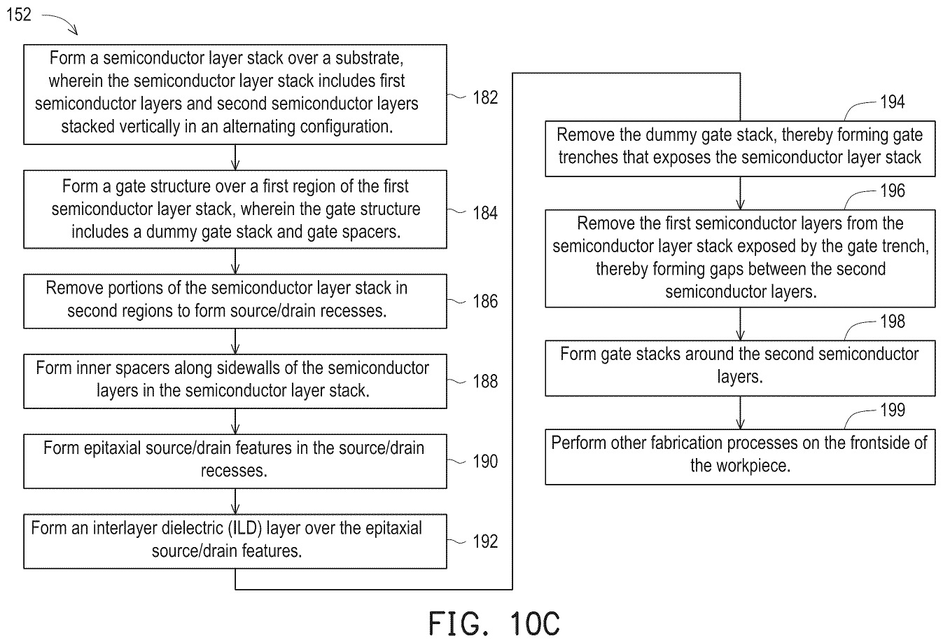

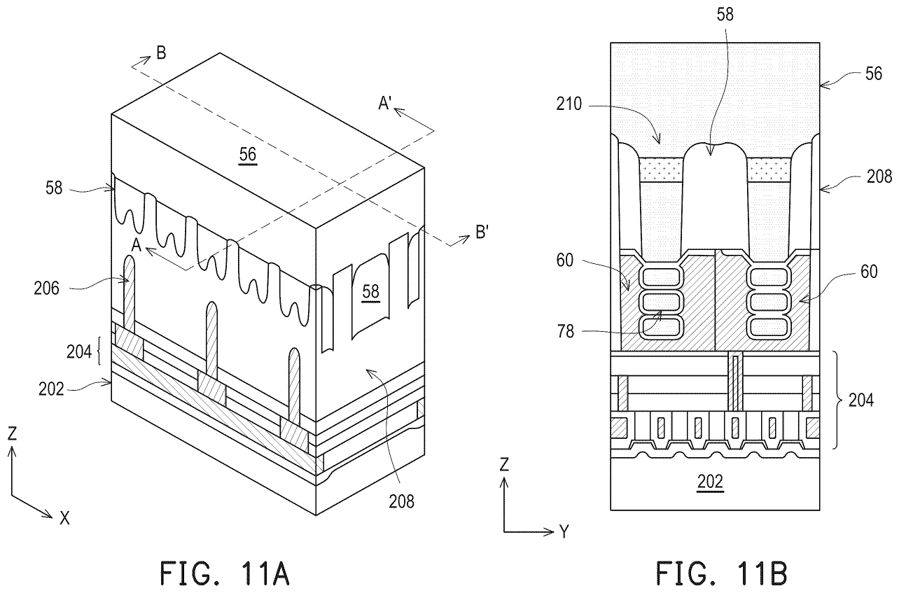

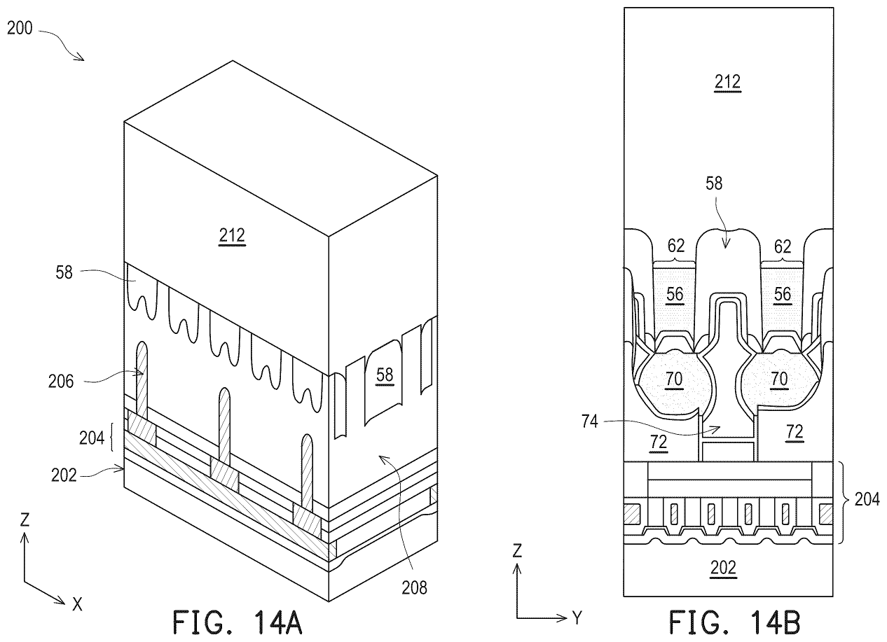

FIGS. 10A, 10B and 10C illustrate a flowchart of a method 150 making the IC structure (or workpiece) 200 constructed according to some embodiments. FIGS. 11A-16B are perspective views or sectional views of the IC structure 200 at various fabrication stages constructed according to some embodiments. Particularly, FIGS. 11A, 12A, 13A, 14A, 15A and 16A are perspective views of the IC structure 200; FIGS. 11B, 12B, and 13A are sectional views of the IC structure 200 along the dashed lines AA′; and FIGS. 14B, 15B, and 16B are sectional views of the IC structure 200 along the dashed lines BB′. The method 150 is further described below with reference to FIGS. 10A-16B according to some embodiments. In some examples, the IC structure (or workpiece) 200 is the IC structure 20 in portion or entirety.

Referring to FIGS. 10A, 11A and 11B, the method 150 begins with a block 152 by providing or receiving a workpiece 200 includes various devices including SRAM devices configured in an array. The devices include FETs in any proper structure, such as planar FETs, fin FETs, GAA FETs, complementary FETs (CFETs), other proper devices or a combination thereof, are formed on the frontside of the semiconductor substrate 56, and an interconnect structure 204, including contacts, vias and metal lines, is formed over the devices. The interconnect structure 204 is also referred to as frontside interconnect structure 204. In the disclosed embodiment, the devices are GAA FETs with gate structures wrapping around each of the vertically stacked multiple channel layers 78.

Note that workpiece 200 is illustrated in FIGS. 11A and 11B upside-down so that the frontside of the substrate 56 is shown on bottom and the backside of the substrate 56 is on top. Especially, an etch stop layer 210 is formed in the semiconductor substrate 56. The etch stop layer 210 functions as etch stop during the backside processes, as to be described at later operations of the method 150. The etch stop layer 210 is embedded in the semiconductor substrate 56 with a material different from the semiconductor substrate 56 for etch selectivity, The etch stop layer 210 includes any proper material to achieve etch selectivity, such as silicon oxide, silicon nitride, other dielectric materials, other suitable materials or a combination thereof. In some embodiments, the semiconductor substrate 56 is a silicon substrate and the etch stop layer 210 is a silicon germanium or silicon oxide. The etch stop layer 210 may be formed in the semiconductor substrate 56 by any suitable method, such as implanted oxygen (SIMOX), or implantation to introduce other composition. In some embodiments, the etch stop layer 210 is formed by an epitaxial growth, such as epitaxially growing a silicon germanium layer on the semiconductor substrate 56 as the etch stop layer; and epitaxially growing a silicon layer on the silicon germanium layer such that the silicon germanium layer is embedded in the semiconductor substrate 56.

The formation of the frontside structures includes forming the devices and the frontside interconnect structure 204 as described above, and further includes forming other features and components, such as gate-cut features 206 and dielectric gates 208. The gate-cut features 206 are dielectric features and are formed to cut long gate structure into segmented gate structures. The gate-cut features 206 may be formed before, during or after the formation of the gate structure 60 and are longitudinally oriented along the X direction while the gate structures 60 are longitudinally oriented along the Y direction. The dielectric gates 208 are dielectric features as well but are longitudinally oriented along the Y direction and are in parallel with the gate structures. In some embodiments, dummy gate structures are formed and then replaced with the gate structures and the dielectric gates 208, respectively. The gate-cut features 206 are formed to cut the gate structures into segmented gate structure 60.

Still referring to FIGS. 10A, 11A and 11B, the method 150 proceeds to an operation 154 by bonding a carrier substrate 202 to the workpiece 200 on the frontside; and an operation 156 to thin down the semiconductor substrate 56 from the backside. At the operation 156, after the bonding, the semiconductor substrate 56 is thinned down from the backside by a suitable technique, such as grinding, chemical mechanical polishing or a combination thereof. In the disclosed embodiment, the thin-down process reduces the thickness of the substrate 56 such that the STI structure 58 is exposed from the backside. The carrier substrate 202 is a semiconductor substrate (such as a silicon substrate), a dielectric substrate or other suitable substrate according to some embodiments.

The detailed operations to form the devices and the interconnect structure are further described in the flowchart of FIG. 10C.

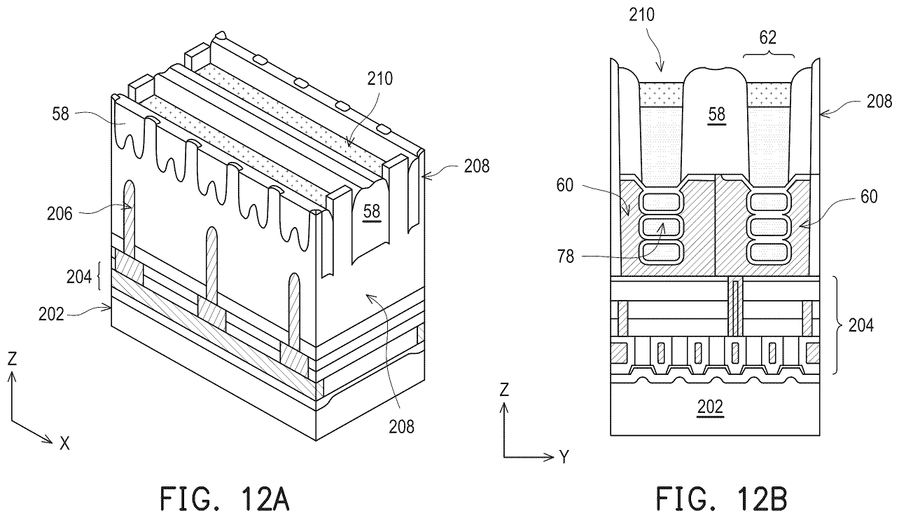

Referring to FIGS. 10A, 12A and 12B, the method 150 proceeds to an operation 158 by performing a wet etch process with an etch solution to selectively etch the semiconductor material of the substrate 56, such as silicon. The wet etch process stops on the etch stop layer 210 due to selective etch so that the etch stop layer 210 is exposed from the backside after the wet etch. In some embodiments, the wet etch process uses potassium hydroxide (KOH) solution, or an etching solution including nitric acid, (HNO3), hydrofluoric acid (HF) and water (H2O).

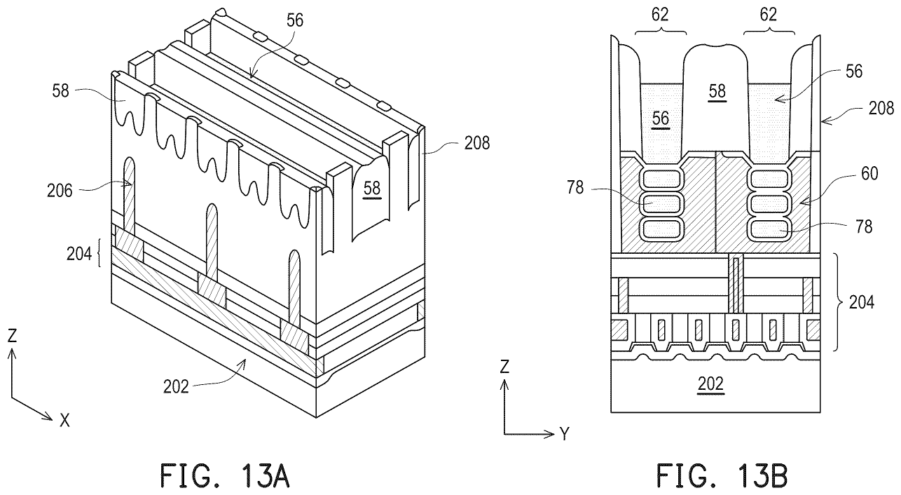

Referring to FIGS. 10A, 13A and 13B, the method 150 proceeds to an operation 160 by selectively removing the etch stop layer 210 by a suitable method, such as another wet etch process with an etchant to selectively remove the etch stop layer 210. Thereafter, the semiconductor substrate 56 with the associated active regions 62 is exposed from backside. In some embodiments, the etching solution includes diluted hydrofluoric acid if the etch stop layer 210 is silicon oxide.

Referring to FIGS. 10A, 14A and 14B, the method 150 proceeds to an operation 162 by depositing a dielectric material layer 212 on the backside using a suitable method such as chemical vapor deposition (CVD), flowable CVD (FCVD), other suitable method or a combination thereof. The dielectric material layer 212 may include silicon oxide, silicon oxynitride, other suitable dielectric material or a combination thereof.

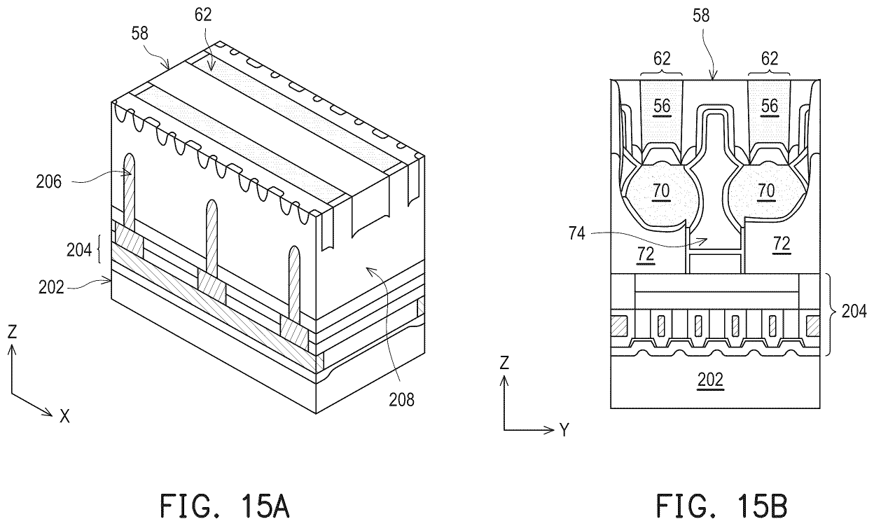

Referring to FIGS. 10A, 15A and 15B, the method 150 proceeds to an operation 164 by performing a CMP process to the backside such that the backside is recessed and planarized until both the STI structure 58 and the semiconductor substrate 56 are exposed from the backside. Accordingly, the bottom surfaces of the STI structure 58 and the semiconductor substrate 56 are coplanar.

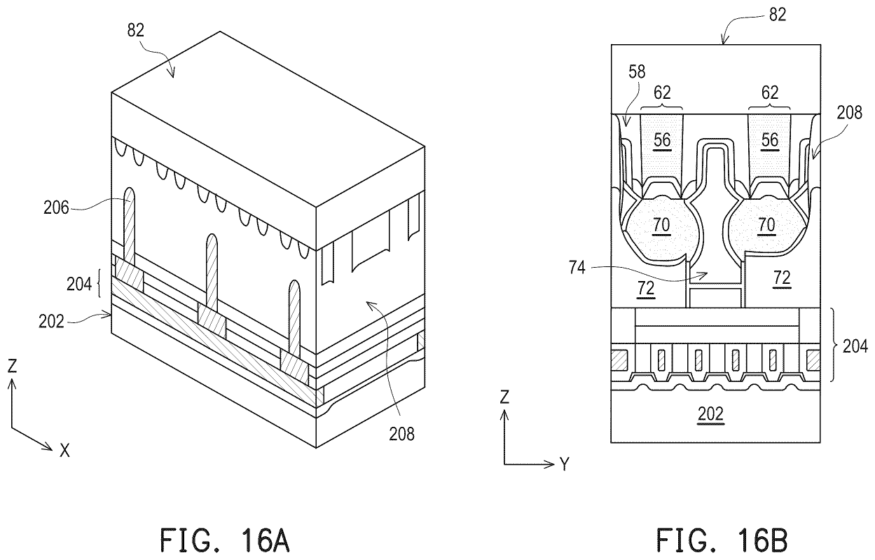

Referring to FIGS. 10A, 16A and 16B, the method 150 proceeds to an operation 166 by forming a backside dielectric layer 82 on the backside using a suitable method such as chemical vapor deposition (CVD), flowable CVD (FCVD), other suitable method or a combination thereof. The backside dielectric layer 82 may include silicon oxide, silicon oxynitride, silicon nitride, other suitable dielectric material or a combination thereof, according to some embodiments. The backside dielectric layer 82 may function as a hard mask, an etch stop layer, dielectric isolation, other functions or a combination thereof.

The method 150 proceeds to an operation 168 to form a backside interconnect structure including backside vias, backside dielectric vias, and backside metal lines distributed in one or more metal layers.

The method 150 may include other processes before, during or after the operations described above.

The backside interconnect structure 63 formed at the operation 168 is similar to the frontside interconnect structure 204 in terms of formation and composition. For example, the backside interconnect structure 63 includes backside vias 64, metal lines 80 and vias distributed in one or more metal layers and can be formed by a suitable technique, such as damascene process, dual damascene process, a procedure including deposition and patterning, other suitable method or a combination thereof. In some embodiments, the backside interconnect structure 63 includes backside vias (or backside vias) 64 and the backside metal lines 80 formed by the methods described in FIGS. 8A-8D and 9A-9B.

For example, as illustrated in FIG. 10B and with further reference to FIGS. 8A-8D and 9A-9B, the method 168 to form the backside interconnect structure 63 includes an operation 170 by patterning the backside dielectric layer 82 and the semiconductor substrate 56 to form contact holes. The backside dielectric layer 82 may functions as a hard mask during the patterning process. The method 168 proceeds an operation 172 by forming a dielectric barrier layer 66 on the sidewalls of the contact holes using a proper technique, such as a procedure that includes depositing one or more dielectric material (such as silicon oxide, silicon nitride, silicon oxynitride or other suitable dielectric material or a combination thereof) and applying a plasma etch to the dielectric material. The method 168 proceeds to an operation 174 by forming metal plugs 64 in the contact holes as illustrated in FIG. 8B. The operation 174 may include deposition and applying a CMP process. The method 168 proceeds to an operation 176 by forming a backside interlayer dielectric layer 84 by a suitable method such as deposition and applying a CMP process. The method 168 proceeds to an operation 178 by patterning the backside interlayer dielectric layer 84 to form trenches. The method 168 proceeds to an operation 180 by forming metal lines in the trenches using a procedure including deposition and CMP process according to some embodiments.

The operation 152 to form the frontside devices (such as GAA FETs or other multi-gate devices) and the frontside interconnect structure 204 includes various operations, such as those illustrated in FIG. 10C.

In some embodiments, the method 152 fabricates a multi-gate device that includes p-type GAA transistors and n-type GAA transistors. In some embodiments, method 102 fabricates a multi-gate device that includes first GAA transistors and second GAA transistors with different characteristics, such as the first GAA transistors in a critical path and the second GAA transistors in a non-critical path. In the present embodiment, a path is defined as a route to distribute signal in a circuit. A critical path is the place that mainly dominates the circuit speed (or signal distribution speed) that is dependent on different circuit applications. On the other hand, if the circuit speed is varied with transistors' performance significantly, then the signal path will be referred to as critical path. In some respects, the critical path and the non-critical GAA path may have different power consumptions during field operations. In an integrated circuit, the electrical current (and also electrical power) in the circuit may be nonuniformly distributed. Average current densities in some local areas are greater than those in other local areas. Those areas with greater average current densities are referred to as critical paths, which leads to various concerns, such as reducing power efficiency, degrading circuit performance, decreasing circuit speed, increasing battery size, and causing reliability issues. In the existing method, device dimensions, such as channel widths of the transistors in the critical paths are increased to adjust or reduce the corresponding average current density. However, the existing method will increase other issues. For example, the circuit areas are increased, and the packing density is reduced. In other examples, adjustment to the dimensions of the devices in the critical paths introduces jog in an active region that further increase circuit layout complexity and challenges circuit design due to the smaller circuit cell height and gate pitch in advanced technology nodes.

The disclosed multigate device and the method making the same addresses those concerns. Particularly, for performance boosting, the present disclosure chooses high driving devices (or devices with greater number sheet number devices) at critical path; and low power devices (or less sheet number devices) at non-critical path.

At block 182, a semiconductor layer stack is formed over a substrate. The semiconductor layer stack includes first semiconductor layers and second semiconductor layers stacked vertically in an alternating configuration. At block 184, a gate structure is formed over a first region of the semiconductor layer stack and. The gate structure includes a dummy gate stack and gate spacers. At block 186, portions of the semiconductor layer stack in second regions are removed to form source/drain recesses. At block 188, inner spacers are formed along sidewalls of the first semiconductor layers in the semiconductor layer stack. At block 190, epitaxial source/drain features are formed in the source/drain recesses. At block 192, an interlayer dielectric (ILD) layer is formed over the epitaxial source/drain features. At block 194, the dummy gate stack is removed, thereby forming a gate trench that exposes the semiconductor layer stack in a gate region. At block 196, the first semiconductor layers are removed from the semiconductor layer stack exposed by the gate trench, thereby forming gaps between the second semiconductor layers. At block 198, gate stacks are formed in the gate trench around the second semiconductor layers in the gate region. At block 199, other fabrication processes, including forming an interconnect structure, are performed from the frontside of the workpiece. Additional processing is contemplated by the present disclosure. Additional steps can be provided before, during, and after method 152, and some of the steps described can be moved, replaced, or eliminated for additional embodiments of method 152.

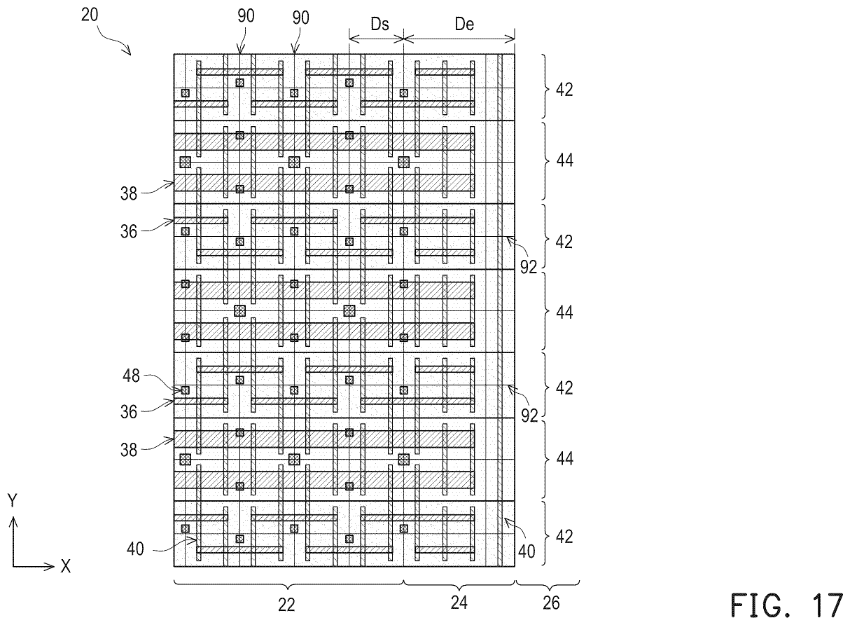

The IC structure 20 may include other layout and configuration according to various embodiments of the present disclosure, such as those illustrated in FIGS. 17 through 24.

FIG. 17 is a top view of the IC structure 20 according to some embodiments. The SRAM region 22 and the edge region 24 of the IC structure 20 are illustrated in FIG. 17. The SRAM region 22 includes multiple SRAM cells configured in an array. The N-wells 42 and P-wells 44 extend from the edge region 24 to the SRAM region 22 and extend through multiple SRAM cells 28 along X direction. The active regions 36 and 38 are formed on the N-well 42 and the P-wells 44, respectively, and are longitudinally oriented along X direction. Especially, the active regions 36 and 38 span different widths along Y direction, as described above, such as FIG. 6A. The gate structures 40 are formed over the active regions and are longitudinally oriented along Y direction. The contacts 90 and vias 48 of the frontside interconnect structure are illustrated. The contacts 90 have elongated shape and longitudinally oriented along Y direction and are landing on the S/D features 70. The vias 48 are configured to land on the contacts 90 and are electrically connect the contacts to metal lines 92 in the first metal layer. The metal lines 92 are longitudinally oriented along X direction. Various circuit features are designed and configured to have robust edge region and reduced dimension of the edge region 24. In the present embodiment, the ratio De/Ds equals to 2.

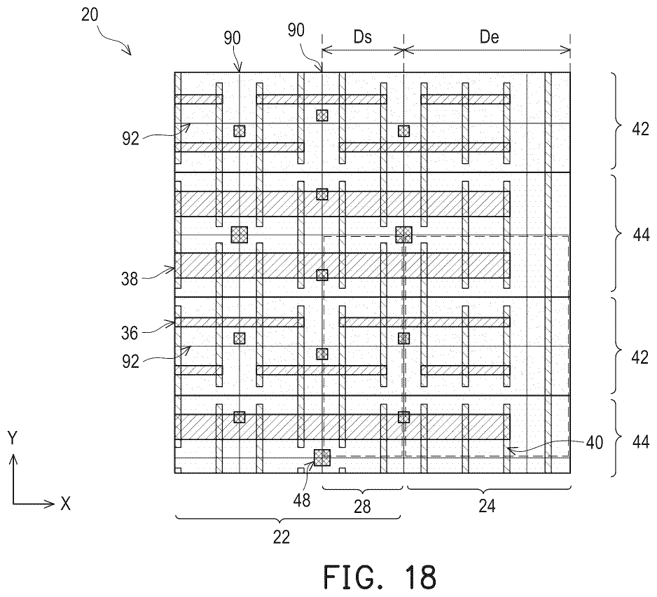

FIG. 18 is a top view of the IC structure 20 according to some embodiments. The SRAM region 22 and the edge region 24 of the IC structure 20 are illustrated in FIG. 18. The SRAM region 22 includes multiple SRAM cells configured in an array. The N-wells 42 and P-wells 44 extend from the edge region 24 to the SRAM region 22 and extend through multiple SRAM cells 28 along X direction. The active regions 36 and 38 are formed on the N-well 42 and the P-wells 44, respectively, and are longitudinally oriented along X direction. Especially, the active regions 36 and 38 span different widths along Y direction, as described above, such as FIG. 6A. The gate structures 40 are formed over the active regions and are longitudinally oriented along Y direction. The contacts 90 and vias 48 of the frontside interconnect structure are illustrated. The contacts 90 have elongated shape and longitudinally oriented along Y direction and are landing on the S/D features 70. The vias 48 are configured to land on the contacts 90 and are electrically connect the contacts to metal lines 92 in the first metal layer. The metal lines 92 are longitudinally oriented along X direction. Various circuit features are designed and configured to have robust edge region and reduced dimension of the edge region 24. In the present embodiment, the ratio De/Ds equals to 2.

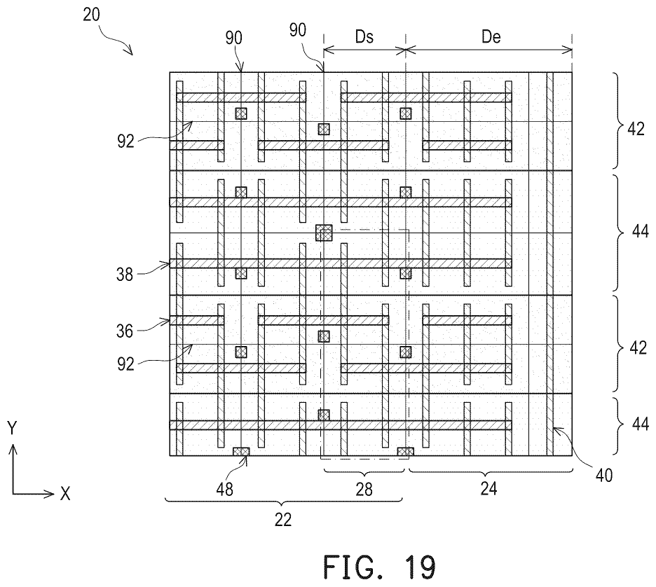

FIG. 19 is a top view of the IC structure 20 according to some embodiments. The SRAM region 22 and the edge region 24 of the IC structure 20 are illustrated in FIG. 19. The SRAM region 22 includes multiple SRAM cells configured in an array. The N-wells 42 and P-wells 44 extend from the edge region 24 to the SRAM region 22 and extend through multiple SRAM cells 28 along X direction. The active regions 36 and 38 are formed on the N-well 42 and the P-wells 44, respectively, and are longitudinally oriented along X direction. Especially, the active regions 36 and 38 span a same width along Y direction, as described above, such as FIG. 6B. The gate structures 40 are formed over the active regions and are longitudinally oriented along Y direction. The contacts 90 and vias 48 of the frontside interconnect structure are illustrated. The contacts 90 have elongated shape and longitudinally oriented along Y direction and are landing on the S/D features 70. The vias 48 are configured to land on the contacts 90 and are electrically connect the contacts to metal lines 92 in the first metal layer. The metal lines 92 are longitudinally oriented along X direction. Various circuit features are designed and configured to have robust edge region and reduced dimension of the edge cell 24. In the present embodiment, the ratio De/Ds equals to 2.

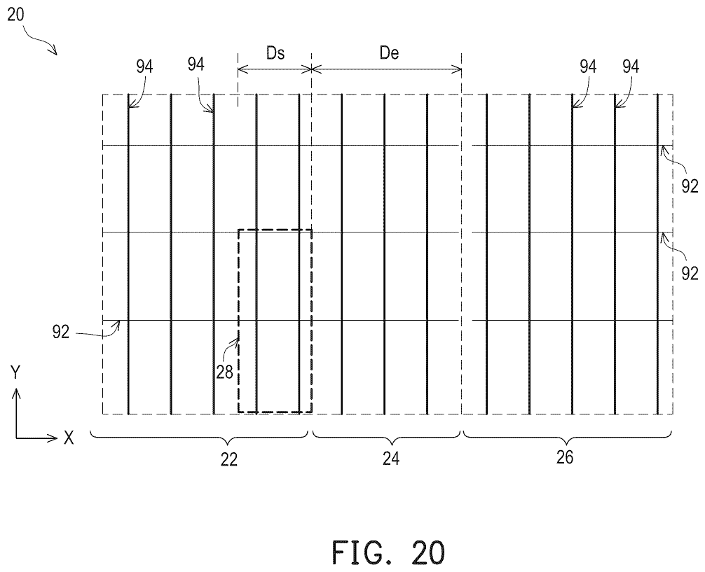

FIG. 20 is a top view of the IC structure 20, in portion, according to some embodiments. The IC structure 20 in FIG. 20 is similar to the IC structure in FIG. 19 but the IOP region 26 and second metal lines 94 are additionally illustrated. Other features, such as active regions and gate structures are not shown for better view. In FIG. 20, portions of the frontside interconnect structure are illustrated, such as first metal lines 92 in the first metal layer and second metal lines 94 in the second metal layer. The layout of the metal lines and configured with other features, such as active regions and gate structures in FIG. 19, to provide proper electric routing, enhanced transition between the SRAM cells 28 in the SRAM region 22 and IOP circuits in the IOP region 26, and reduced packing area of the edge region 24.

FIG. 21 is a top view of the IC structure 20 according to some embodiments. The SRAM region 22 and the edge region 24 of the IC structure 20 are illustrated in FIG. 21. The SRAM region 22 includes multiple SRAM cells configured in an array. The N-wells 42 and P-wells 44 extend from the edge region 24 to the SRAM region 22 and extend through multiple SRAM cells 28 along X direction. The active regions 36 and 38 are formed on the N-well 42 and the P-wells 44, respectively, and are longitudinally oriented along X direction. Especially, the active regions 36 and 38 span different widths along Y direction, as described above, such as FIG. 6A. The gate structures 40 are formed over the active regions and are longitudinally oriented along Y direction. The contacts 90 and vias 48 of the frontside interconnect structure are illustrated. The contacts 90 have elongated shape and longitudinally oriented along Y direction and are landing on the S/D features 70. The vias 48 are configured to land on the contacts 90 and are electrically connect the contacts to metal lines 92 in the first metal layer. The metal lines 92 are longitudinally oriented along X direction. Various circuit features are designed and configured to have robust edge region and reduced dimension of the edge region 24. In the present embodiment, the edge region 24 is further reduced by dimension. Da1=1.5*Pg, Da2=0.5*Pg and Dc=Pg. Furthermore, Ds=2*Pg, De=3*Pg and the ratio De/Ds equals to 1.5, being less than 2.

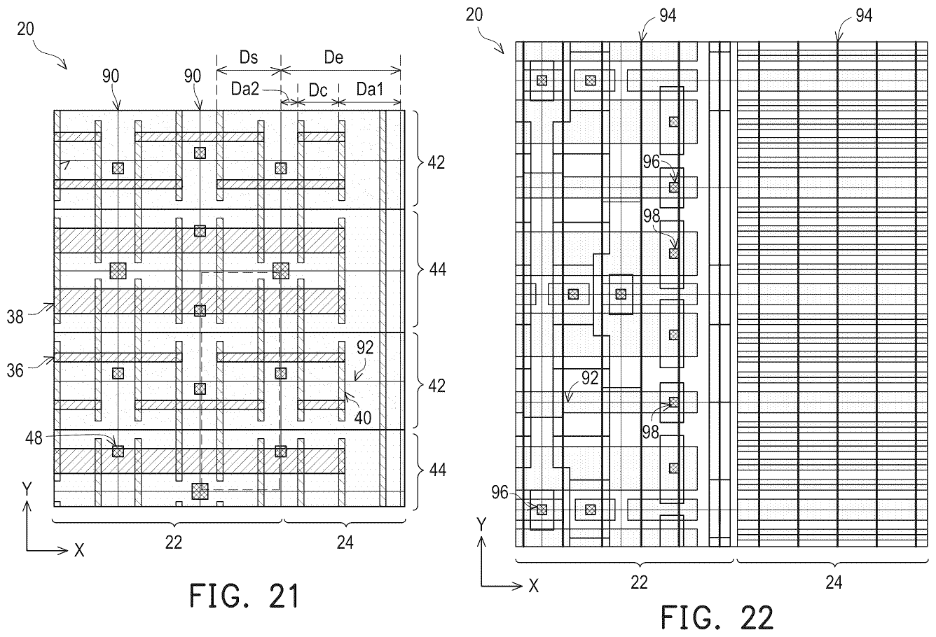

FIG. 22 is a top view of the IC structure 20, in portion, according to some embodiments. The IC structure 20 in FIG. 22 is similar to the IC structure in FIG. 21 but second metal lines 94 are additionally illustrated. Other features, such as active regions and gate structures are not shown for better view. In FIG. 22, portions of the frontside interconnect structure are illustrated, such as first metal lines 92 in the first metal layer, second metal lines 94 in the second metal layer, and vias 96 vertically connecting respective first metal lines 92 and second metal lines 94. Various circuit features are designed and configured to have robust edge region and reduced dimension of the edge region 24. For examples, the IC structure 20 further includes vias 98 away from any intersection of a first metal line 92 and a second metal line 94. In this case, vias 98 vertically extends from a contact 90 to a second metal line 94. This connect is referred to as a jumper, which provides flexibility of metal lines and saves the circuit area when the IOP region 26 and the SRAM region 22 are configured differently, such as the first metal lines in the IOP region 26 may have different pitch (or spacing) than the first metal lines in the SRAM region 22. The layout of the metal lines and configured with other features, such as active regions and gate structures in FIG. 21, to provide proper electric routing, enhanced transition between the SRAM cells 28 in the SRAM region 22 and IOP circuits in the IOP region 26, and reduced packing area of the edge region 24.

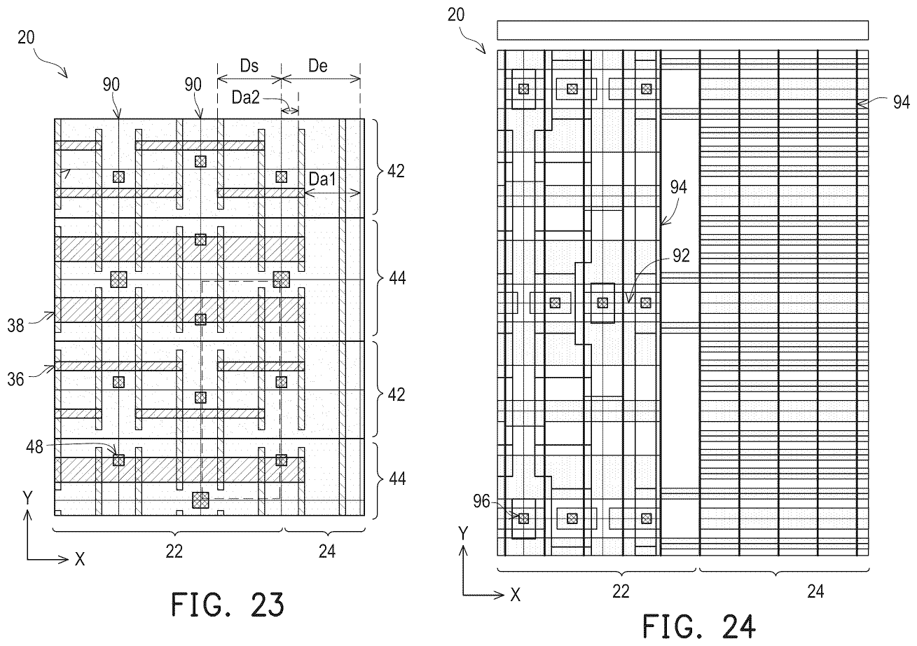

FIG. 23 is a top view of the IC structure 20 according to some embodiments. The SRAM region 22 and the edge region 24 of the IC structure 20 are illustrated in FIG. 23. The SRAM region 22 includes multiple SRAM cells configured in an array. The N-wells 42 and P-wells 44 extend from the edge region 24 to the SRAM region 22 and extend through multiple SRAM cells 28 along X direction. The active regions 36 and 38 are formed on the N-well 42 and the P-wells 44, respectively, and are longitudinally oriented along X direction. Especially, the active regions 36 and 38 span different widths along Y direction, as described above, such as FIG. 6A. The gate structures 40 are formed over the active regions and are longitudinally oriented along Y direction. The contacts 90 and vias 48 of the frontside interconnect structure are illustrated. The contacts 90 have elongated shape and longitudinally oriented along Y direction and are landing on the S/D features 70. The vias 48 are configured to land on the contacts 90 and are electrically connect the contacts to metal lines 92 in the first metal layer. The metal lines 92 are longitudinally oriented along X direction. Various circuit features are designed and configured to have robust edge region and reduced dimension of the edge region 24. For example, the edge region 24 has no dummy active regions but only portions of the active regions in the SRAM region 22 extend to the edge region 24 with a length of 0.5*Pg or less. In the present embodiment, the edge region 24 is further reduced by dimension. Da1=1.5*Pg, Da2=0.5*Pg and Dc=Pg. Da2 is defined as the distance of the end of the active regions to the boundary line of the SRAM region 22. Furthermore, Ds=2*Pg, De=2*Pg and the ratio De/Ds equals to 1, being less than 2.

FIG. 24 is a top view of the IC structure 20, in portion, according to some embodiments. The IC structure 20 in FIG. 22 is similar to the IC structure in FIG. 23 but second metal lines 94 are additionally illustrated. Other features, such as active regions and gate structures are not shown for better view. In FIG. 22, portions of the frontside interconnect structure are illustrated, such as first metal lines 92 in the first metal layer, second metal lines 94 in the second metal layer, and vias 96 vertically connecting respective first metal lines 92 and second metal lines 94. The layout of the metal lines and configured with other features, such as active regions and gate structures in FIG. 21, to provide proper electric routing, enhanced transition between the SRAM cells 28 in the SRAM region 22 and IOP circuits in the IOP region 26, and reduced packing area of the edge region 24.

The present disclosure provides for many different embodiments. The disclosed device structure and the method making the same are related to a SRAM structure including field-effect transistors (FETs), especially GAA FET structure in various layout and configuration. The disclosed device structure includes various structure features and fabrication steps to provide collective isolation and prevent the device structure from current leakage. The edge region between the SRAM region and the IOP region is substantially reduced in size. De/Ds equals to 2 or is less than 2, such as 1.5 or 1. The disclosed structure having SRAM device structure and the method making the same is taken as an example. Furthermore, the disclosed structure and method are also compatible with other fabrication technologies without enhanced the circuit packing density and power efficiency.

The present disclosure provides integrated circuit structures and methods for fabricating such are disclosed herein. In one example aspect, an exemplary integrated circuit structure includes a semiconductor substrate having a static random-access memory (SRAM) region, an input/output and peripheral (IOP) region, and an edge region spanning tween the SRAM region and the IOP region; a shallow trench isolation (STI) structure formed on the semiconductor substrate and defining active regions; a SRAM cell formed within the SRAM region; and a backside dielectric layer disposed on a backside of the semiconductor substrate and landing on a bottom surface of the STI structure. The active regions are longitudinally oriented along a first direction; a plurality of gates are formed on the semiconductor substrate and longitudinally oriented along a second direction perpendicular to the first direction; the gates are evenly distributed with a pitch P along the first direction; the SRAM cell spans a first dimension Ds along the first direction; the edge region spans a second dimension De along the first direction; and a ratio De/Ds equals to 2 or is less than 2.

In another example aspect, the present disclosure provides an IC structure that includes a semiconductor substrate having a static random-access memory (SRAM) region, an input/output and peripheral (IOP) region, and an edge region spanning tween the SRAM region and the IOP region; a n-type doped well continuously extending through the SRAM region and the edge region along a first direction; a p-type doped well continuously extending through the SRAM region and the edge region along the first direction; a shallow trench isolation (STI) structure formed on the semiconductor substrate and defined a first, second and third active regions longitudinally oriented along the first direction; a plurality of gates longitudinally oriented along a second direction perpendicular to the first direction, wherein the gates are evenly distributed in the SRAM region and the edge region with a periodic pitch P; and a backside dielectric layer contacting a bottom surface of the semiconductor substrate and a bottom surface of the STI structure. The SRAM region includes SRAM cells each spanning a first dimension Ds along the first direction; the edge region spans a second dimension De along the first direction; and a ratio De/Ds equals to 2 or is less than 2.

In yet another example aspect, the present disclosure provides a method of making an integrated circuit (IC) structure. The method includes receiving a semiconductor substrate having a frontside and a backside, wherein the semiconductor substrate includes a static random-access memory (SRAM) region, an input/output and peripheral (IOP) region, and an edge region spanning tween the SRAM region and the IOP region; forming a SRAM structure having SRAM cells in the SRAM region on the frontside of the semiconductor substrate; forming an interconnect structure over the SRAM structure; thinning down the semiconductor substrate from the backside such that is a shallow trench isolation (STI) structure is exposed from the backside; and forming a backside dielectric layer directly on a bottom surface of the STI structure and a bottom surface of the semiconductor substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) structure, comprising:
a semiconductor substrate having a static random-access memory (SRAM) region, an input/output and peripheral (IOP) region, and an edge region spanning tween the SRAM region and the IOP region;
a shallow trench isolation (STI) structure formed on the semiconductor substrate and defining active regions;
a SRAM cell formed within the SRAM region, the SRAM cell including field-effect transistors (FETs) configured to form two inverters cross-coupled and two pass ports, one of the FETs includes multiple channel layers vertically stacked and spaced from each other, and a first and second source/drain features disposed on opposite sides of the channel layers and connecting to the channel layers; and
a backside dielectric layer disposed on a backside of the semiconductor substrate and landing on a bottom surface of the STI structure, wherein
the active regions longitudinally are oriented along a first direction,
gates are formed on the semiconductor substrate and longitudinally oriented along a second direction perpendicular to the first direction,
the gates are evenly distributed with a pitch P along the first direction,
the SRAM cell spans a first dimension Ds along the first direction,
the edge region spans a second dimension De along the first direction, and
a ratio De/Ds equals to 2 or is less than 2.

2. The IC structure of claim 1, wherein Ds equals to 2P and De equals to 4P.

3. The IC structure of claim 1, wherein Ds equals to 2P and De equals to 2P.

4. The IC structure of claim 1, wherein the bottom surface of the STI structure and a bottom surface of the semiconductor substrate are coplanar.

5. The IC structure of claim 1, wherein one of the gates disposed on the one of the FETs and is further extending to wrap around each of the multiple channel layers.

6. The IC structure of claim 5, wherein the first source/drain feature further includes a dielectric material layer embedded in an epitaxial semiconductor feature.

7. The IC structure of claim 6, further comprising a backside conductive via formed on the backside of the semiconductor substrate and landing on the second source/drain feature, wherein
the backside conductive via is partially embedded in the semiconductor substrate; and
the backside conductive via includes a conductive plug with a dielectric layer surrounding a sidewall of the conductive plug and separating the conductive plug from the semiconductor substrate.

8. The IC structure of claim 7, wherein a bottom surface of the backside conductive via is coplanar with a bottom surface of the backside dielectric layer.

9. The IC structure of claim 7, further comprising a backside dielectric via formed on the backside of the semiconductor substrate, wherein the backside dielectric via is surrounded by the semiconductor substrate and laterally contacts the backside dielectric layer, and wherein the backside dielectric via is landing a bottom surface of a third source/drain feature.

10. An integrated circuit structure, comprising:
a semiconductor substrate having a static random-access memory (SRAM) region, an input/output and peripheral (IOP) region, and an edge region spanning tween the SRAM region and the IOP region;
a n-type doped well continuously extending through the SRAM region and the edge region along a first direction;
a p-type doped well continuously extending through the SRAM region and the edge region along the first direction;
a shallow trench isolation (STI) structure formed on the semiconductor substrate and defined a first, second and third active regions longitudinally oriented along the first direction;
a plurality of gates longitudinally oriented along a second direction perpendicular to the first direction, wherein the gates are evenly distributed in the SRAM region and the edge region with a periodic pitch P;
a backside dielectric layer contacting a bottom surface of the semiconductor substrate and a bottom surface of the STI structure; and
backside conductive vias embedded in the semiconductor substrate and penetrating through the backside dielectric layer, wherein
the SRAM region includes SRAM cells each spanning a first dimension Ds along the first direction,
the edge region spans a second dimension De along the first direction, and
a ratio De/Ds equals to 2 or is less than 2.

11. The IC structure of claim 10, wherein
the first active region formed in the p-type doped well and continuously extending from the SRAM region to the edge region;
the second active region formed in the n-type doped well and disposed within the SRAM region; and
the third active region formed in the n-type doped well and disposed within the edge region.

12. The IC structure of claim 11, wherein
the first active region spans a first width W1 along the second direction;
the second and third active regions span a second width W2 along the second direction, W1 being greater than W2; and
the second and third active regions are aligned along the first direction.

13. The IC structure of claim 11, further comprising
a first source/drain (S/D) feature formed on the first active region; and
a second S/D feature formed on the second active region, wherein the backside conductive vias includes a first backside conductive via contacting a bottom surface of the first S/D feature, and a second conductive backside via contacting a bottom surface of the second S/D feature.

14. The IC structure of claim 13, wherein each of the first and second conductive backside vias is partially embedded in the semiconductor substrate and includes a conductive plug with a dielectric layer surrounding a sidewall of the conductive plug and separating the conductive plug from the semiconductor substrate.

15. The IC structure of claim 13, further comprising a backside dielectric via formed on the backside of the semiconductor substrate, wherein the backside dielectric via is surrounded by the semiconductor substrate and laterally contacts the backside dielectric layer.

16. The IC structure of claim 10, wherein
Ds equals to 2P and De equals to 4P; and
the bottom surface of the STI structure and the bottom surface of the semiconductor substrate are coplanar.

17. A method of making an integrated circuit (IC) structure, comprising:
receiving a semiconductor substrate having a frontside and a backside, wherein the semiconductor substrate includes a static random-access memory (SRAM) region, an input/output and peripheral (IOP) region, and an edge region spanning tween the SRAM region and the IOP region;
forming a SRAM structure having SRAM cells in the SRAM region on the frontside of the semiconductor substrate;
forming an interconnect structure over the SRAM structure;
thinning down the semiconductor substrate from the backside such that is a shallow trench isolation (STI) structure is exposed from the backside;
forming a backside dielectric layer directly on a bottom surface of the STI structure and a bottom surface of the semiconductor substrate; and
forming backside conductive vias in the semiconductor substrate from the backside, wherein the conductive via penetrates through the backside dielectric layer.

18. The method of claim 17, wherein the forming a SRAM structure having SRAM cells further includes
forming a n-type doped well continuously extending through the SRAM region and the edge region along a first direction;
forming a p-type doped well continuously extending through the SRAM region and the edge region along the first direction;
forming a first, second and third active regions longitudinally oriented along the first direction and surrounded by the STI structure; and
forming a plurality of gates longitudinally oriented along a second direction perpendicular to the first direction, wherein the gates are evenly distributed in the SRAM region and the edge region with a periodic pitch P, wherein
each of the SRAM cells spans a first dimension Ds along the first direction,
the edge region spans a second dimension De along the first direction, and
a ratio De/Ds equals to 2.

19. The method of claim 18, wherein
the first active region formed in the p-type doped well and continuously extending from the SRAM region to the edge region;
the second active region formed in the n-type doped well and disposed within the SRAM region; and
the third active region formed in the n-type doped well and disposed within the edge region.

20. The method of claim 18, further comprising
forming a first source/drain (S/D) feature on the first active region with a first dielectric feature isolating the first S/D feature from the semiconductor substrate; and
forming a second S/D feature on the second active region with a second dielectric feature isolating the second S/D feature from the semiconductor substrate, wherein the backside conductive vias includes a first backside conductive via contacting a bottom surface of the first S/D feature, and a second conductive backside via contacting a bottom surface of the second S/D feature, and wherein each of the first and second backside vias is partially embedded in the semiconductor substrate and includes a conductive plug with a dielectric layer surrounding a sidewall of the conductive plug and separating the conductive plug from the semiconductor substrate.
